(19) United States
(12) Patent Application Publication
(10) Pub. No.: US 2026/0222153 A1
(43) Pub. Date: Jul. 30, 2026

(54) MULTIPLE POLAR CODING SEQUENCES

(71) Applicant: QUALCOMM Incorporated, San Diego, CA (US)

(72) Inventors: Kirill IVANOV, La Jolla, CA (US); Wei YANG, San Diego, CA (US)

(21) Appl. No.: 19/041,705

(22) Filed: Jan. 30, 2025

(51) Int. Cl. H04L 5/00; H04W 72/21

(52) U.S. Cl. CPC H04L 5/0053; H04W 72/21

(57) ABSTRACT

Various aspects of the present disclosure generally relate to wireless communication. In some aspects, a wireless communication device may receive control signaling indicating a configuration for a communication. The wireless communication device may select one of a uniform polar code sequence or a nonuniform polar code sequence based at least in part on the configuration for the communication. The wireless communication device may derive, based at least in part on a polar code sequence that is selected, a polar code for encoding a plurality of bits to generate a polar codeword for the communication. The wireless communication device may encode the plurality of bits using the polar code to generate the polar codeword. The wireless communication device may transmit the polar codeword within the communication. Numerous other aspects are described.

### FIELD OF THE DISCLOSURE

Aspects of the present disclosure generally relate to wireless communication and specifically relate to techniques, apparatuses, and methods associated with multiple polar coding sequences.

### BACKGROUND

Wireless communication systems are widely deployed to provide various services, which may involve carrying or supporting voice, text, other messaging, video, data, and/or other traffic. Typical wireless communication systems may employ multiple-access radio access technologies (RATs) capable of supporting communication among multiple wireless communication devices including user devices or other devices by sharing the available system resources (for example, time domain resources, frequency domain resources, spatial domain resources, and/or device transmit power, among other examples). Such multiple-access RATs are supported by technological advancements that have been adopted in various telecommunication standards, which define common protocols that enable different wireless communication devices to communicate on a local, municipal, national, regional, or global level.

An example telecommunication standard is New Radio (NR). NR, which may also be referred to as 5G, is part of a continuous mobile broadband evolution promulgated by the Third Generation Partnership Project (3GPP). NR (and other RATs beyond NR) may be designed to better support enhanced mobile broadband (eMBB) access, Internet of things (IoT) networks or reduced capability device deployments, and ultra-reliable low latency communication (URLLC) applications. To support these verticals, NR systems may be designed to implement a modularized functional infrastructure, a disaggregated and service-based network architecture, network function virtualization, network slicing, multi-access edge computing, millimeter wave (mmWave) technologies including massive multiple-input multiple-output (MIMO), licensed and unlicensed spectrum access, non-terrestrial network (NTN) deployments, sidelink and other device-to-device direct communication technologies (for example, cellular vehicle-to-everything (CV2X) communication), multiple-subscriber implementations, high-precision positioning, and/or radio frequency (RF) sensing, among other examples. As the demand for connectivity continues to increase, further improvements in NR may be implemented, and other RATs, such as 6G and beyond, may be introduced to enable new applications and facilitate new use cases.

In some wireless communication networks, wireless communication devices (such as network nodes or user equipments (UEs)) may communicate using polar codes. That is, a transmitting device may perform one or more polar encoding operations (such as corresponding to one or more polar codes) on a set of information bits to obtain a polar encoded codeword.

### SUMMARY

Some aspects described herein relate to a method for wireless communication at a wireless communication device. The method may include receiving control signaling indicating a configuration for a communication. The method may include selecting one of a uniform polar code sequence or a nonuniform polar code sequence based at least in part on the configuration for the communication. The method may include deriving, based at least in part on a polar code sequence that is selected, a polar code for encoding a plurality of bits to generate a polar codeword for the communication. The method may include encoding the plurality of bits using the polar code to generate the polar codeword. The method may include transmitting the polar codeword within the communication.

Some aspects described herein relate to a method for wireless communication at a wireless communication device. The method may include receiving control signaling indicating a configuration for a communication. The method may include receiving the communication based at least in part on the configuration, wherein the communication comprises a polar codeword. The method may include selecting one of a uniform polar code sequence or a nonuniform polar code sequence based at least in part on the configuration for the communication. The method may include deriving, based at least in part on a polar code sequence that is selected, a polar code for decoding the polar codeword to obtain a plurality of bits. The method may include decoding the polar codeword using the polar code to obtain the plurality of bits.

Some aspects described herein relate to an apparatus for wireless communication at a wireless communication device. The apparatus may include one or more memories and one or more processors coupled to the one or more memories. The one or more processors may be configured to receive control signaling indicating a configuration for a communication. The one or more processors may be configured to select one of a uniform polar code sequence or a nonuniform polar code sequence based at least in part on the configuration for the communication. The one or more processors may be configured to derive, based at least in part on a polar code sequence that is selected, a polar code for encoding a plurality of bits to generate a polar codeword for the communication. The one or more processors may be configured to encode the plurality of bits using the polar code to generate the polar codeword. The one or more processors may be configured to transmit the polar codeword within the communication.

Some aspects described herein relate to an apparatus for wireless communication at a wireless communication device. The apparatus may include one or more memories and one or more processors coupled to the one or more memories. The one or more processors may be configured to receive control signaling indicating a configuration for a communication. The one or more processors may be configured to receive the communication based at least in part on the configuration, wherein the communication comprises a polar codeword. The one or more processors may be configured to select one of a uniform polar code sequence or a nonuniform polar code sequence based at least in part on the configuration for the communication. The one or more processors may be configured to derive, based at least in part on a polar code sequence that is selected, a polar code for decoding the polar codeword to obtain a plurality of bits. The one or more processors may be configured to decode the polar codeword using the polar code to obtain the plurality of bits.

Some aspects described herein relate to a non-transitory computer-readable medium that stores a set of instructions for wireless communication by a wireless communication device. The set of instructions, when executed by one or more processors of the wireless communication device, may cause the wireless communication device to receive control signaling indicating a configuration for a communication. The set of instructions, when executed by one or more processors of the wireless communication device, may cause the wireless communication device to select one of a uniform polar code sequence or a nonuniform polar code sequence based at least in part on the configuration for the communication. The set of instructions, when executed by one or more processors of the wireless communication device, may cause the wireless communication device to derive, based at least in part on a polar code sequence that is selected, a polar code for encoding a plurality of bits to generate a polar codeword for the communication. The set of instructions, when executed by one or more processors of the wireless communication device, may cause the wireless communication device to encode the plurality of bits using the polar code to generate the polar codeword. The set of instructions, when executed by one or more processors of the wireless communication device, may cause the wireless communication device to transmit the polar codeword within the communication.

Some aspects described herein relate to a non-transitory computer-readable medium that stores a set of instructions for wireless communication by a wireless communication device. The set of instructions, when executed by one or more processors of the wireless communication device, may cause the wireless communication device to receive control signaling indicating a configuration for a communication. The set of instructions, when executed by one or more processors of the wireless communication device, may cause the wireless communication device to receive the communication based at least in part on the configuration, wherein the communication comprises a polar codeword. The set of instructions, when executed by one or more processors of the wireless communication device, may cause the wireless communication device to select one of a uniform polar code sequence or a nonuniform polar code sequence based at least in part on the configuration for the communication. The set of instructions, when executed by one or more processors of the wireless communication device, may cause the wireless communication device to derive, based at least in part on a polar code sequence that is selected, a polar code for decoding the polar codeword to obtain a plurality of bits. The set of instructions, when executed by one or more processors of the wireless communication device, may cause the wireless communication device to decode the polar codeword using the polar code to obtain the plurality of bits.

Some aspects described herein relate to an apparatus for wireless communication. The apparatus may include means for receiving control signaling indicating a configuration for a communication. The apparatus may include means for selecting one of a uniform polar code sequence or a nonuniform polar code sequence based at least in part on the configuration for the communication. The apparatus may include means for deriving, based at least in part on a polar code sequence that is selected, a polar code for encoding a plurality of bits to generate a polar codeword for the communication. The apparatus may include means for encoding the plurality of bits using the polar code to generate the polar codeword. The apparatus may include means for transmitting the polar codeword within the communication.

Some aspects described herein relate to an apparatus for wireless communication. The apparatus may include means for receiving control signaling indicating a configuration for a communication. The apparatus may include means for receiving the communication based at least in part on the configuration, wherein the communication comprises a polar codeword. The apparatus may include means for selecting one of a uniform polar code sequence or a nonuniform polar code sequence based at least in part on the configuration for the communication. The apparatus may include means for deriving, based at least in part on a polar code sequence that is selected, a polar code for decoding the polar codeword to obtain a plurality of bits. The apparatus may include means for decoding the polar codeword using the polar code to obtain the plurality of bits.

Aspects of the present disclosure may generally be implemented by or as a method, apparatus, system, computer program product, non-transitory computer-readable medium, user equipment, base station, network node, network entity, wireless communication device, and/or processing system as substantially described with reference to, and as illustrated by, this specification and accompanying drawings.

The foregoing paragraphs of this section have broadly summarized some aspects of the present disclosure. These and additional aspects and associated advantages will be described hereinafter. The disclosed aspects may be used as a basis for modifying or designing other aspects for carrying out the same or similar purposes of the present disclosure. Such equivalent aspects do not depart from the scope of the appended claims. Characteristics of the aspects disclosed herein, both their organization and method of operation, together with associated advantages, will be better understood from the following description when considered in connection with the accompanying drawings.

### BRIEF DESCRIPTION OF THE DRAWINGS

The appended drawings illustrate some aspects of the present disclosure but are not limiting of the scope of the present disclosure because the description may enable other aspects. Each of the drawings is provided for purposes of illustration and description, and not as a definition of the limits of the claims. The same or similar reference numbers in different drawings may identify the same or similar elements.

FIG. 1 is a diagram illustrating an example of a wireless communication network, in accordance with the present disclosure.

FIG. 2 is a diagram illustrating an example disaggregated network node architecture, in accordance with the present disclosure.

FIG. 3 is a diagram illustrating an example of a systematic polar encoding operation, in accordance with the present disclosure.

FIG. 4 is a diagram illustrating an example wireless communication network, in accordance with the present disclosure.

FIG. 5 is a diagram illustrating an example associated with multiple polar code sequences, in accordance with the present disclosure.

FIGS. 6 and 7 are diagrams illustrating example processes performed, for example, at a wireless communication device or an apparatus of a wireless communication device, in accordance with the present disclosure.

FIG. 8 is a diagram of an example apparatus for wireless communication, in accordance with the present disclosure.

### DETAILED DESCRIPTION

Various aspects of the present disclosure are described hereinafter with reference to the accompanying drawings. However, aspects of the present disclosure may be embodied in many different forms. The present disclosure is not to be construed as limited to any specific aspect illustrated by or described with reference to an accompanying drawing or otherwise presented in this disclosure. Rather, these aspects are provided so that this disclosure will be thorough and complete, and will fully convey the scope of the disclosure to those skilled in the art. One skilled in the art may appreciate that the scope of the disclosure is intended to cover any aspect of the disclosure disclosed herein, whether implemented independently of or in combination with any other aspect of the disclosure. For example, an apparatus may be implemented or a method may be practiced using various combinations or quantities of the aspects set forth herein. In addition, the scope of the disclosure is intended to cover an apparatus having, or a method that is practiced using, other structures and/or functionalities in addition to or other than the structures and/or functionalities with which various aspects of the disclosure set forth herein may be practiced. Any aspect of the disclosure disclosed herein may be embodied by one or more elements of a claim.

Several aspects of telecommunication systems will now be presented with reference to various methods, operations, apparatuses, and techniques. These methods, operations, apparatuses, and techniques will be described in the following detailed description and illustrated in the accompanying drawings by various blocks, modules, components, circuits, steps, processes, or algorithms (collectively referred to as “elements”). These elements may be implemented using hardware, software, or a combination of hardware and software. Whether such elements are implemented as hardware or software depends upon the particular application and design constraints imposed on the overall system.

In some wireless communication systems, wireless communication devices (such as network nodes or user equipments (UEs)) may communicate using polar codes. That is, a transmitting wireless communication device may perform a polar encoding operation (such as corresponding to one or more polar codes) on a set of information bits to obtain a polar encoded codeword. In some cases, the polar code may correspond to a non-systematic polar code or a systematic polar code. For non-systematic polar codes, the set of information bits may not appear directly in the non-systematically polar encoded codeword. Additionally, for systematic polar codes, the set of information bits may appear directly in the systematically polar encoded codeword.

Accordingly, a transmitting wireless communication device may polar encode a source (e.g., a plurality of bits) and transmit the polar encoded codeword to a receiving wireless device. The source may correspond to a uniformly distributed source or a nonuniformly distributed source. In some examples, a uniformly distributed source may correspond to a source that is associated with symbols or data that are equally likely to be each value within a set of predefined values (e.g., that are equally likely to be a ‘0’ or a ‘1’). For example, if the source is associated with transmitting symbols from an alphabet size of N, then the probability P of each symbol occurring when the source is uniformly distributed would be equal (e.g., the probability P=1/N). In some other examples, a uniformly distributed source may correspond to a source that has a conditional uniform distribution of symbols. That is, some receiving wireless communication devices may determine additional distribution information about a source (e.g., side information). If the source has a conditional uniform distribution of symbols, then even once the receiving wireless communication device determines the additional distribution information about the source, the probability of each possible symbol occurring is still equal.

A nonuniformly distributed source may correspond to a source that is associated with symbols or data that are not equally likely to be each value within the set of predefined values. For example, if the source is associated with transmitting symbols from an alphabet size of N, then the probability P of each symbol occurring when the source is nonuniformly distributed would not be equal (e.g., the probability P of one or more of P₀, . . . , P_{N}≠1/N). In some other examples, a nonuniformly distributed source may correspond to a source that has a conditional nonuniform distribution of symbols. That is, some receiving wireless communication devices may determine additional distribution information about a source. If the source has a conditional nonuniform distribution of symbols, then the receiving wireless communication device may determine the additional distribution information about the source and determine that the probability of each possible symbol occurring is not equal.

A polar code sequence that is used by a transmitting wireless communication device to polar encode a plurality of bits to generate a codeword may be designed for uniformly distributed sources. Here, a uniformly distributed source that is polar encoded using the polar code sequence may be associated with an increased efficiency as compared to a nonuniformly distributed source that is polar encoded using the polar code sequence. That is, polar code sequences that are designed for polar encoding uniformly distributed sources may introduce unnecessary overhead when used for polar encoding nonuniformly distributed sources (e.g., may introduce overhead without improving or without significantly improving a reliability of a transmission of the polar encoded codeword).

Various aspects relate generally to supporting multiple polar code sequences for wireless communications. Some aspects more specifically relate to a transmitting wireless communication device selecting a polar code sequence for encoding a set of bits from a uniform polar code sequence (e.g., a polar code sequence that is designed for uniformly distributed sources) and a nonuniform polar code sequence (e.g., a polar code sequence that is designed for nonuniformly distributed sources). In some aspects, a network node may transmit control signaling to a wireless communication device indicating a configuration for a communication. The configuration may indicate to the wireless communication device whether to use the uniform polar code sequence or the nonuniform polar code sequence for encoding or decoding the communication. Then the wireless communication device may use the selected polar code sequence (e.g., the uniform polar code sequence or the nonuniform polar code sequence) for deriving a polar code to encode or decode the communication in accordance with the configuration.

Particular aspects of the subject matter described in this disclosure can be implemented to realize one or more of the following potential advantages. In some examples, the described techniques can be used to improve an efficiency of communications. In particular, by selecting a polar code sequence based on whether a source is uniformly or nonuniformly distributed, wireless communication devices may improve an efficiency of polar encoded communications (e.g., particularly for nonuniformly distributed sources).

As described above, wireless communication systems may be deployed to provide various services, which may involve carrying or supporting voice, text, other messaging, video, data, and/or other traffic. Some wireless communications systems may employ multiple-access radio access technologies (RATs). The multiple-access RATs may be capable of supporting communication with multiple wireless communication devices by sharing the available system resources (for example, time domain resources, frequency domain resources, spatial domain resources, and/or device transmit power, among other examples). Examples of such multiple-access RATs include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

Multiple-access RATs are supported by technological advancements that have been adopted in various telecommunication standards, which define common protocols that enable wireless communication devices to communicate on a local, municipal, enterprise, national, regional, or global level. For example, 5G New Radio (NR) is part of a continuous mobile broadband evolution promulgated by the Third Generation Partnership Project (3GPP). 5G NR may support enhanced mobile broadband (eMBB) access, Internet of Things (IoT) networks or reduced capability (RedCap) device deployments, ultra-reliable low-latency communication (URLLC) applications, and/or massive machine-type communication (mMTC), among other examples.

To support these and other target verticals, a wireless communication system may be designed to implement a modularized functional infrastructure, a disaggregated and service-based network architecture, network function virtualization, network slicing, multi-access edge computing, millimeter wave (mmWave) technologies including massive multiple-input multiple-output (MIMO), beamforming, IoT device or RedCap device connectivity and management, industrial connectivity, licensed and unlicensed spectrum access, sidelink and other device-to-device direct communication (for example, cellular vehicle-to-everything (CV2X) communication), frequency spectrum expansion, overlapping spectrum use, small cell deployments, non-terrestrial network (NTN) deployments, device aggregation, advanced duplex communication (for example, sub-band full-duplex (SBFD)), multiple-subscriber implementations, high-precision positioning, radio frequency (RF) sensing, network energy savings (NES), low-power signaling and radios, and/or artificial intelligence or machine learning (AI/ML), among other examples.

The foregoing and other technological improvements may support use cases, such as wireless fronthauls, wireless midhauls, wireless backhauls, wireless data centers, extended reality (XR) and metaverse applications, meta services for supporting vehicle connectivity, holographic and mixed reality communication, autonomous and collaborative robots, vehicle platooning and cooperative maneuvering, sensing networks, gesture monitoring, human-brain interfacing, digital twin applications, asset management, and universal coverage applications using non-terrestrial and/or aerial platforms, among other examples.

As the demand for connectivity continues to increase, further improvements in NR may be implemented, and other RATs, such as 6G and beyond, may be introduced to enable new applications and facilitate new use cases. The methods, operations, apparatuses, and techniques described herein may enable one or more of the foregoing technologies or new technologies and/or support one or more of the foregoing use cases or new use cases.

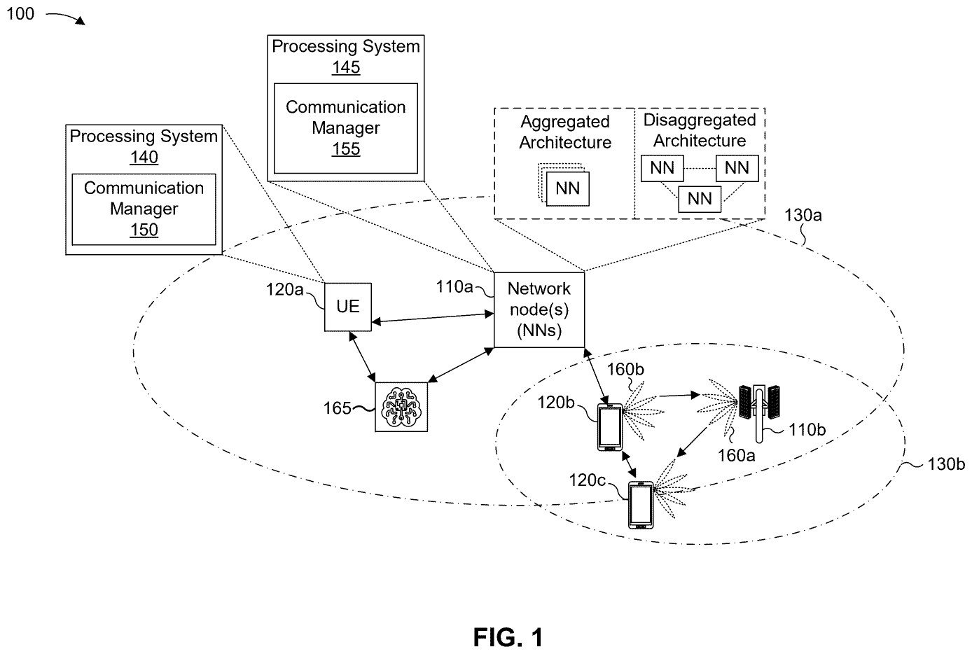

FIG. 1 is a diagram illustrating an example of a wireless communication network 100, in accordance with the present disclosure. The wireless communication network 100 may be or may include elements of a 5G (or NR) network or a 6G network, among other examples. The wireless communication network 100 may include multiple network nodes 110. For example, in FIG. 1, the wireless communication network 100 includes a network node (NN) 110a and a network node 110b. The network nodes 110 may support communications with multiple UEs 120. For example, in FIG. 1, the network nodes 110 support communication with a UE 120a, a UE 120b, and a UE 120c. In some examples, a UE 120 may also communicate with other UEs 120 and a network node 110 may communicate with a core network and with other network nodes 110.

The network nodes 110 and the UEs 120 of the wireless communication network 100 may communicate using the electromagnetic spectrum, which may be subdivided by frequency or wavelength into various classes, bands, carriers, and/or channels. For example, devices of the wireless communication network 100 may communicate using one or more operating bands. In some aspects, multiple wireless communication networks 100 may be deployed in a given geographic area. Each wireless communication network 100 may support a particular RAT (which may also be referred to as an air interface) and may operate on one or more carrier frequencies in one or more frequency bands or ranges. In some examples, when multiple RATs are deployed in a given geographic area, each RAT in the geographic area may operate on different frequencies to avoid interference with other RATs. Additionally, or alternatively, in some examples, the wireless communication network 100 may implement dynamic spectrum sharing (DSS), in which multiple RATs are implemented with dynamic bandwidth allocation (for example, based on user demand) in a single frequency band. In some examples, the wireless communication network 100 may support communication over unlicensed spectrum, where access to an unlicensed channel is subject to a channel access mechanism. For example, in a shared or unlicensed frequency band, a transmitting device may perform a channel access procedure, such as a listen-before-talk (LBT) procedure, to contend against other devices for channel access before transmitting on a shared or unlicensed channel.

Various operating bands have been defined as frequency range designations FR1 (410 MHz through 7.125 GHz), FR2 (24.25 GHz through 52.6 GHz), FR3 (7.125 GHz through 24.25 GHz), FR4a or FR4-1 (52.6 GHz through 71 GHz), FR4 (52.6 GHz through 114.25 GHZ), and FR5 (114.25 GHz through 300 GHz). Although a portion of FR1 is greater than 6 GHZ, FR1 is often referred to (interchangeably) as a “sub-6 GHz” band in some documents and articles. Similarly, FR2 is often referred to (interchangeably) as a “millimeter wave” band in some documents and articles, despite being different than the extremely high frequency (EHF) band (30 GHz through 300 GHz), which is identified by the International Telecommunications Union (ITU) as a “millimeter wave” band. The frequencies between FR1 and FR2 are often referred to as mid-band frequencies, which include FR3. Frequency bands falling within FR3 may inherit FR1 characteristics or FR2 characteristics, and thus may effectively extend features of FR1 or FR2 into the mid-band frequencies. Thus, “sub-6 GHZ,” if used herein, may broadly refer to frequencies that are less than 6 GHZ, that are within FR1, and/or that are included in mid-band frequencies. Similarly, the term “millimeter wave,” if used herein, may broadly refer to mid-band frequencies or to frequencies that are within FR2, FR4, FR4-a or FR4-1, FR5, and/or the EHF band. Higher frequency bands may extend 5G NR operation, 6G operation, and/or other RATs beyond 52.6 GHz.

A network node 110 and/or a UE 120 may include one or more devices, components, or systems that enable communication with other devices, components, or systems of the wireless communication network 100. For example, a UE 120 and a network node 110 may each include one or more chips, system-on-chips (SoCs), chipsets, packages, or devices that individually or collectively constitute or comprise a processing system, such as a processing system 140 of the UE 120 or a processing system 145 of the network node 110. A processing system (for example, the processing system 140 and/or the processing system 145) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), and/or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform various functions or operations described herein. A group of processors collectively configurable or configured to perform a set of functions may include a first processor configurable or configured to perform a first function of the set and a second processor configurable or configured to perform a second function of the set. In some other examples, each of a group of processors may be configurable or configured to perform a same set of functions.

The processing system 140 and the processing system 145 may each include memory circuitry in the form of one or multiple memory devices, memory blocks, memory elements, or other discrete gate or transistor logic or circuitry, each of which may include or implement tangible storage media such as random-access memory (RAM) or read-only memory (ROM), or combinations thereof (any one or more of which may be generally referred to herein individually as a “memory” or collectively as “the memory” or “the memory circuitry”). One or more of the memories may be coupled (for example, operatively coupled, communicatively coupled, electronically coupled, or electrically coupled) with one or more of the processors and may individually or collectively store processor-executable code or instructions (such as software) that, when executed by one or more of the processors, may configure one or more of the processors to perform various functions or operations described herein. Additionally, or alternatively, in some examples, one or more of the processors may be configured to perform various functions or operations described herein without requiring configuration by software. “Software” shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

The processing system 140 and the processing system 145 may each include or be coupled with one or more modems (such as a cellular (for example, a 5G or 6G compliant) modem). In some examples, one or more processors of the processing system 140 and/or the processing system 145 include or implement one or more of the modems. The processing system 140 and the processing system 145 may also include or be coupled with multiple radios (collectively “the radio”), multiple RF chains, or multiple transceivers, each of which may in turn be coupled with one or more of multiple antennas. In some examples, one or more processors of the processing system 140 and/or the processing system 145 include or implement one or more of the radios, RF chains, or transceivers. An RF chain may include one or more filters, mixers, oscillators, amplifiers, analog-to-digital converters (ADCs), and/or other devices that convert between an analog signal (such as for transmission or reception via an air interface) and a digital signal (such as for processing by the processing system 140 of the UE 120 or by the processing system 145 of the network node 110).

A network node 110 and a UE 120 may each include one or multiple antennas or antenna arrays. Typical network nodes 110 and UEs 120 may include multiple antennas, which may be organized or structured into one or more antenna panels, one or more antenna groups, one or more sets of antenna elements, or one or more antenna arrays, among other examples. As used herein, the term “antenna” can refer to one or more antennas, one or more antenna panels, one or more antenna groups, one or more sets of antenna elements, or one or more antenna arrays. The term “antenna panel” can refer to a group of antennas (such as antenna elements) arranged in an array or panel, which may facilitate beamforming by manipulating parameters associated with the group of antennas. The term “antenna module” may refer to circuitry including one or more antennas as well as one or more other components (such as filters, amplifiers, or processors) associated with integrating the antenna module into a wireless communication device such as the network node 110 and the UE 120.

A network node 110 may be, may include, or may also be referred to as an NR network node, a 5G network node, a 6G network node, a Node B, a gNB, an access point (AP), a transmission reception point (TRP), a network entity, a network element, a network equipment, and/or another type of device, component, or system included in a radio access network (RAN). In various deployments, a network node 110 may be implemented as a single physical node (for example, a single physical structure) or may be implemented as two or more physical nodes (for example, two or more distinct physical structures). For example, a network node 110 may be a device or system that implements a part of a radio protocol stack, a device or system that implements a full radio protocol stack (such as a full gNB protocol stack), or a collection of devices or systems that collectively implement the full radio protocol stack. For example, and as shown, a network node 110 may be an aggregated network node having an aggregated architecture, meaning that the network node 110 may implement a full radio protocol stack that is physically and logically integrated within a single physical structure in the wireless communication network 100. For example, an aggregated network node 110 may consist of a single standalone base station or a single TRP that operates with a full radio protocol stack to enable or facilitate communication between a UE 120 and a core network of the wireless communication network 100.

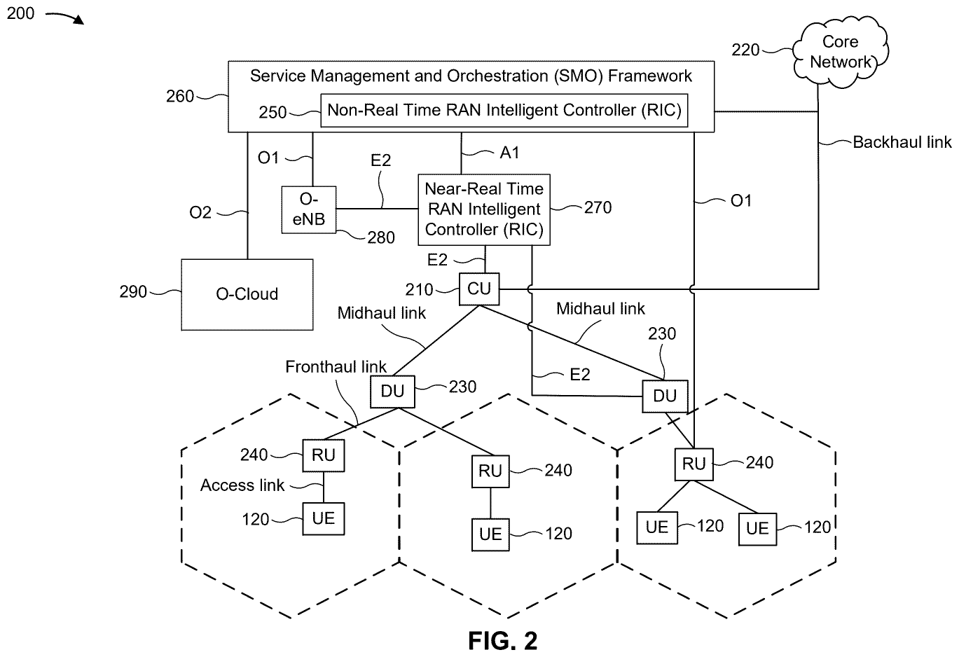

Alternatively, and as also shown, a network node 110 may be a disaggregated network node (sometimes referred to as a disaggregated base station), having a disaggregated architecture, meaning that the network node 110 may operate with a radio protocol stack that is physically distributed and/or logically distributed among two or more nodes in the same geographic location or in different geographic locations. An example disaggregated network node architecture is described in more detail below with reference to FIG. 2. In some deployments, disaggregated network nodes 110 may be used in an integrated access and backhaul (IAB) network, in an open radio access network (O-RAN) (such as a network configuration in compliance with the O-RAN Alliance), or in a virtualized radio access network (vRAN), also known as a cloud radio access network (C-RAN), to facilitate scaling by separating network functionality into multiple units or modules that can be individually deployed.

The network nodes 110 of the wireless communication network 100 may include one or more central units (CUs), one or more distributed units (DUs), and one or more radio units (RUs). A CU may host one or more higher layers, such as a radio resource control (RRC) layer, a packet data convergence protocol (PDCP) layer, and a service data adaptation protocol (SDAP) layer, among other examples. A DU may host one or more of a radio link control (RLC) layer, a medium access control (MAC) layer, and/or one or more higher physical (PHY) layers depending, at least in part, on a functional split, such as a functional split defined by the 3GPP. In some examples, a DU also may host a lower PHY layer that is configured to perform functions, such as a fast Fourier transform (FFT), an inverse FFT (IFFT), beamforming, and/or physical random access channel (PRACH) extraction and filtering, among other examples. An RU may perform RF processing functions or lower PHY layer functions, such as an FFT, an IFFT, beamforming, or PRACH extraction and filtering, among other examples, according to a functional split, such as a lower layer split (LLS). In such an architecture, each RU can be operated to handle over the air (OTA) communication with one or more UEs 120. In some examples, a single network node 110 may include a combination of one or more CUs, one or more DUs, and/or one or more RUs. In some examples, a CU, a DU, and/or an RU may be implemented as a virtual unit, such as a virtual central unit (VCU), a virtual distributed unit (VDU), or a virtual radio unit (VRU), among other examples, which may be implemented as a virtual network function, such as in a cloud deployment.

Some network nodes 110 (for example, a base station, an RU, or a TRP) may provide communication coverage for a particular geographic area. The term “cell” can refer to a coverage area of a network node 110 or to a network node 110 itself, depending on the context in which the term is used. A network node 110 may support one or more cells (for example, each cell may support communication within an angular (for example, 60 degree) range around the network node). In some examples, a network node 110 may provide communication coverage for a macro cell, a pico cell, a femto cell, or another type of cell. A macro cell may cover a relatively large geographic area (for example, several kilometers in radius) and may allow unrestricted access by UEs 120 with associated service subscriptions. A pico cell may cover a relatively small geographic area and may also allow unrestricted access by UEs 120 with associated service subscriptions. A femto cell may cover a relatively small geographic area (for example, a home) and may allow restricted access by UEs 120 having association with the femto cell (for example, UEs 120 in a closed subscriber group (CSG)). In some examples, a cell may not necessarily be stationary. For example, the geographic area of the cell may move according to the location of an associated mobile network node 110 (for example, a train, a satellite, an unmanned aerial vehicle, or an NTN network node).

The wireless communication network 100 may be a heterogeneous network that includes network nodes 110 of different types, such as macro network nodes, pico network nodes, femto network nodes, relay network nodes, aggregated network nodes, and/or disaggregated network nodes, among other examples. Various different types of network nodes 110 may generally transmit at different power levels, serve different coverage areas (for example, a cell 130a and a cell 130b), and/or have different impacts on interference in the wireless communication network 100 than other types of network nodes 110.

The UEs 120 may be physically dispersed throughout the coverage area of the wireless communication network 100, and each UE 120 may be stationary or mobile. A UE 120 may be, may include, or may also be referred to as an access terminal, a mobile station, or a subscriber unit. A UE 120 may be, include, or be coupled with a cellular phone (for example, a smart phone), a personal digital assistant (PDA), a wireless modem, a wireless communication device, a handheld device, a laptop computer, a cordless phone, a wireless local loop (WLL) station, a tablet, a camera, a netbook, a smartbook, an ultrabook, a medical device, a biometric device, a wearable device (for example, a smart watch, smart clothing, smart glasses, a smart wristband, or smart jewelry), a gaming device, an entertainment device (for example, a music device, a video device, or a satellite radio), an XR device, a vehicular component or sensor, a smart meter or sensor, industrial manufacturing equipment, a Global Navigation Satellite System (GNSS) device (such as a Global Positioning System device or another type of positioning device), a UE function of a network node, and/or any other suitable device or function that may communicate via a wireless medium.

Some UEs 120 may be classified according to different categories in association with different complexities and/or different capabilities. UEs 120 in a first category may facilitate massive IoT in the wireless communication network 100, and may offer low complexity and/or cost relative to UEs 120 in a second category. UEs 120 in a second category may include mission-critical IoT devices, legacy UEs, baseline UEs, high-tier UEs, advanced UEs, full-capability UEs, and/or premium UEs that are capable of URLLC, eMBB, and/or precise positioning in the wireless communication network 100, among other examples. A third category of UEs 120 may have mid-tier complexity and/or capability (for example, a capability between that of the UEs 120 of the first category and that of the UEs 120 of the second capability). A UE 120 of the third category may be referred to as a reduced capability UE (“RedCap UE”), a mid-tier UE, an NR-Light UE, and/or an NR-Lite UE, among other examples. RedCap UEs may bridge a gap between the capability and complexity of NB-IoT devices and/or enhanced machine type communication (eMTC) UEs, and mission-critical IoT devices and/or premium UEs. RedCap UEs may include, for example, wearable devices, IoT devices, industrial sensors, or cameras that are associated with a limited bandwidth, power capacity, and/or transmission range, among other examples. RedCap UEs may support healthcare environments, building automation, electrical distribution, process automation, transport and logistics, or smart city deployments, among other examples.

In some examples, a network node 110 may be, may include, or may operate as an RU, a TRP, or a base station that communicates with one or more UEs 120 via a radio access link (which may be referred to as a “Uu” link). The radio access link may include a downlink and an uplink. “Downlink” (or “DL”) refers to a communication direction from a network node 110 to a UE 120, and “uplink” (or “UL”) refers to a communication direction from a UE 120 to a network node 110. Downlink and uplink resources may include time domain resources (for example, frames, subframes, slots, and symbols), frequency domain resources (for example, frequency bands, component carriers (CCs), subcarriers, resource blocks, and resource elements), and spatial domain resources (for example, particular transmit directions or beams).

Frequency domain resources may be subdivided into bandwidth parts (BWPs). A BWP may be a block of frequency domain resources (for example, a continuous set of resource blocks (RBs) within a full component carrier bandwidth) that may be configured at a UE-specific level. A UE 120 may be configured with both an uplink BWP and a downlink BWP (which may be the same or different). Each BWP may be associated with its own numerology (indicating a sub-carrier spacing (SCS) and cyclic prefix (CP)). A BWP may be dynamically configured or activated (for example, by a network node 110 transmitting a downlink control information (DCI) configuration to the one or more UEs 120) and/or reconfigured (for example, in real-time or near-real-time) according to changing network conditions in the wireless communication network 100 and/or specific requirements of one or more UEs 120. An active BWP defines the operating bandwidth of the UE 120 within the operating bandwidth of the serving cell. The use of BWPs enables more efficient use of the available frequency domain resources in the wireless communication network 100 because fewer frequency domain resources may be allocated to a BWP for a UE 120 (which may reduce the quantity of frequency domain resources that a UE 120 is required to monitor and reduce UE power consumption by enabling the UE to monitor fewer frequency domain resources), leaving more frequency domain resources to be spread across multiple UEs 120. Thus, BWPs may also assist in the implementation of lower-capability (for example, RedCap) UEs 120 by facilitating the configuration of smaller bandwidths for communication by such UEs 120 and/or by facilitating reduced UE power consumption.

As used herein, a downlink signal may be or include a reference signal, control information, or data. For example, downlink reference signals include a primary synchronization signal (PSS), a secondary SS (SSS), an SS block (SSB) (for example, that includes a PSS, an SSS, and a physical broadcast channel (PBCH)), a demodulation reference signal (DMRS), a phase tracking reference signal (PTRS), a tracking reference signal (TRS), and a channel state information (CSI) reference signal (CSI-RS), among other examples. A downlink signal carrying control information or data may be transmitted via a downlink channel. Downlink channels may include one or more control channels for transmitting control information and one or more data channels for transmitting data. Downlink reference signals may be transmitted in addition to, or multiplexed with, downlink control channel communications and/or downlink data channel communications. A downlink control channel may be specifically used to transmit DCI from a network node 110 to a UE 120. DCI generally contains the information the UE 120 needs to identify RBs in a subsequent subframe and how to decode them, including a modulation and coding scheme (MCS) or redundancy version parameters. Different DCI formats carry different information, such as scheduling information in the form of downlink or uplink grants, slot format indicators (SFIs), preemption indicators (PIs), transmit power control (TPC) commands, hybrid automatic repeat request (HARQ) information, new data indicators (NDIs), among other examples. A downlink data channel may be used to transmit downlink data (for example, user data associated with a UE 120) from a network node 110 to a UE 120. Downlink control channels may include physical downlink control channels (PDCCHs), and downlink data channels may include physical downlink shared channels (PDSCHs). Control information or data communications may be transmitted on a PDCCH and PDSCH, respectively. For example, a PDCCH can carry DCI, while a PDSCH can carry a MAC control element (MAC-CE), an RRC message, or user data, among other examples. Each PDSCH may carry one or more transport blocks (TBs) of data.

As used herein, an uplink signal may include a reference signal, control information, or data. For example, uplink reference signals include a sounding reference signal (SRS), a PTRS, and a DMRS, among other examples. An uplink signal carrying control information or data may be transmitted via an uplink channel. An uplink channel may include one or more control channels for transmitting control information and one or more data channels for transmitting data. Uplink reference signals may be transmitted in addition to, or multiplexed with, uplink control channel communications and/or uplink data channel communications. An uplink control channel may be specifically used to transmit uplink control information (UCI) from a UE 120 to a network node 110. An uplink data channel may be used to transmit uplink data (for example, user data associated with a UE 120) from a UE 120 to a network node 110. Uplink control channels may include physical uplink control channels (PUCCHs), and uplink data channels may include physical uplink shared channels (PUSCHs). Control information or data communications may be transmitted on a PUCCH and PUSCH, respectively. For example, a PUCCH can carry UCI, while a PUSCH can carry a MAC-CE, an RRC message, or user data, among other examples. UCI can include a scheduling request (SR), HARQ feedback information (for example, a HARQ message such as a HARQ acknowledgement (ACK) indication or a HARQ negative acknowledgement (NACK) indication), uplink power control information (for example, an uplink TPC parameter), and/or CSI, among other examples. CSI can include a channel quality indicator (CQI) (indicative of downlink channel conditions to facilitate selection of transmission parameters, such as an MCS, by a network node 110), a precoding matrix indicator (PMI), a CSI-RS resource indicator (CRI) (for example, indicative of a beam used to transmit a CSI-RS), an SS/PBCH resource block indicator (SSBRI) (for example, indicative of a beam used to transmit an SSB), a layer indicator (LI), a rank indicator (RI), and/or measurement information (for example, a layer 1 (L1)-reference signal received power (RSRP) parameter, a received signal strength indicator (RSSI) parameter, a reference signal received quality (RSRQ) parameter, among other examples) which can be used for beam management, among other examples. Each PUSCH may carry one or more TBs of data.

The information (for example, data, control information, or reference signal information) transmitted by a network node 110 to a UE 120, or vice versa, may be represented as a sequence of binary bits that are mapped (for example, modulated) to an analog signal waveform (for example, a discrete Fourier transform (DFT)-spread-orthogonal frequency division multiplexing (OFDM) (DFT-s-OFDM) waveform or a CP-OFDM waveform) that is transmitted by the network node 110 or UE 120 over a wireless communication channel. In some examples, the network node 110 or the UE 120 (for example, using the processing system 145 or the processing system 140, respectively) may select an MCS (for example, an order of quadrature amplitude modulation (QAM), such as 64-QAM, 128-QAM, or 256-QAM, among other examples) for a downlink signal or an uplink signal. For example, the network node 110 may select an MCS for a downlink signal in accordance with UCI received from the UE 120. The network node 110 may transmit, to the UE 120, an indication of the selected MCS for the downlink signal, such as via DCI that schedules the downlink signal. As another example, the network node 110 may transmit, and the UE 120 may receive, an indication of an MCS to be applied for the one or more uplink signals, such as via DCI scheduling transmission of the one or more uplink signals.

The network node 110 or the UE 120 (such as by using the processing system 145 or the processing system 140, respectively, and/or one or more coupled modems) may perform signal processing on the information (such as filtering, amplification, modulation, digital-to-analog conversion, an IFFT operation, multiplexing, interleaving, mapping, and/or encoding, among other examples) to generate a processed signal in accordance with the selected MCS. In some examples, the network node 110 or the UE 120 (for example, using the processing system 145 or the processing system 140, respectively, and/or one or more coupled encoders or modems) may perform a channel coding operation or a forward error correction (FEC) operation to control errors in transmitted information. For example, the network node 110 or the UE 120 may perform an encoding operation to generate encoded information (such as by selectively introducing redundancy into the information, typically using an error correction code (ECC), such as a polar code or a low-density parity-check (LDPC) code). The network node 110 or the UE 120 (for example, using the processing system 145 and/or one or more modems) may further perform spatial processing (for example, precoding) on the encoded information to generate one or more processed or precoded signals for downlink or uplink transmission, respectively. In some examples, the network node 110 or the UE 120 may perform codebook-based precoding or non-codebook-based precoding. Codebook-based precoding may involve selecting a precoder (for example, a precoding matrix) using a codebook. For example, the network node 110 may provide precoding information indicating which precoder, defined by the codebook, is to be used by the UE 120. Non-codebook-based precoding may involve selecting or deriving a precoder based on, or otherwise associated with, one or more downlink or uplink signal measurements. The network node 110 or the UE 120 may transmit the processed downlink or uplink signals, respectively, via one or more antennas.

In the wireless communication network 100, information may be represented as a sequence of binary bits that are mapped (for example, modulated) to an analog signal waveform that is transmitted to a receiver over a wireless communication channel. In some cases, however, the wireless communication channel may introduce errors that corrupt the transmitted signal due to random noise, interference, device impairments, and/or other factors. At the receiver, the received signal (that may have been corrupted during transmission) is mapped back to binary bits, with the received binary information estimating the transmitted binary information. Accordingly, because errors may corrupt the signal that is estimated at the receiver, channel coding or FEC techniques are often used to control errors in data transmission over unreliable or noisy communication channels or otherwise mitigate the bit errors that may occur due to noise, interference, and/or other factors. For example, channel coding generally includes an encoding operation performed at a transmitter (for example, a wireless communication device, which may be a UE 120 or a network node 110) and a decoding operation performed at a receiver (for example, a second wireless device, which may be a UE 120 or a network node 110). Channel coding is generally accomplished by selectively introducing redundancy into the transmitted information stream, typically using an ECC, which allows the receiver to detect errors and/or correct bit errors in the received data stream and thereby provide more reliable information transmission. Accordingly, channel codes are often used in scenarios where retransmissions are undesirable and/or high transmission reliability is needed, such as downlink and/or uplink control channel communications.

The network node 110 or the UE 120 may receive uplink signals or downlink signals, respectively, via one or more antennas. The network node 110 or the UE 120 (for example, using the processing system 145 or the processing system 140, respectively, and/or one or more coupled modems) may perform signal processing (for example, in accordance with the MCS) on the received uplink or downlink signals, respectively (such as filtering, amplification, demodulation, analog-to-digital conversion, an FFT operation, demultiplexing, deinterleaving, de-mapping, equalization, interference cancellation, and/or decoding, among other examples), to map the received signal(s) to a sequence of binary bits (for example, received information) that estimates the information transmitted by the network node 110 or the UE 120 via the downlink or uplink signals. The network node 110 or the UE 120 (for example, using the processing system 145 or the processing system 140, respectively, and/or a coupled decoder or one or more modems) may decode the received information (such as by using an ECC, a decoding operation, and/or an FEC operation) to detect errors and/or correct bit errors in the received information to generate decoded information. The decoded information may estimate the information transmitted via the downlink or uplink signals.

In some examples, a UE 120 and a network node 110 may perform MIMO communication. “MIMO” generally refers to transmitting or receiving multiple signals (such as multiple layers or multiple data streams) simultaneously over the same time and frequency resources. MIMO techniques generally exploit multipath propagation. A network node 110 and/or UE 120 may communicate using massive MIMO, multi-user MIMO, or single-user MIMO, which may involve rapid switching between beams or cells. For example, the amplitudes and/or phases of signals transmitted via antenna elements and/or sub-elements may be modulated and shifted relative to each other (such as by manipulating a phase shift, a phase offset, and/or an amplitude) to generate one or more beams, which is referred to as beamforming. For example, the network node 110b may generate one or more beams 160a, and the UE 120b may generate one or more beams 160b. The term “beam” may refer to a directional transmission of a wireless signal toward a receiving device or otherwise in a desired direction, a directional reception of a wireless signal from a transmitting device or otherwise in a desired direction, a direction associated with a directional transmission or directional reception, a set of directional resources associated with a signal transmission or signal reception (for example, an angle of arrival, a horizontal direction, and/or a vertical direction), a set of parameters that indicate one or more aspects of a directional signal, a direction associated with the signal, and/or a set of directional resources associated with the signal, among other examples.

MIMO may be implemented using various spatial processing or spatial multiplexing operations. In some examples, MIMO may include a massive MIMO technique which may be associated with an increased (for example, “massive”) quantity of antennas at the network node 110 and/or at the UE 120, such as in a network implementing mmWave technology. Massive MIMO may improve communication reliability by enabling a network node 110 and/or a UE 120 to communicate the same data across different propagation (or spatial) paths. In some examples, MIMO may support simultaneous transmission to multiple receivers, referred to as multi-user MIMO (MU-MIMO). Some RATs may employ MIMO techniques, such as multi-TRP (mTRP) operation (including redundant transmission or reception on multiple TRPs), reciprocity in the time domain or the frequency domain, single-frequency-network (SFN) transmission, or non-coherent joint transmission (NC-JT).

To support MIMO techniques, the network node 110 and the UE 120 may perform one or more beam management operations, such as an initial beam acquisition operation, one or more beam refinement operations, and/or a beam recovery operation. For example, an initial beam acquisition operation may involve the network node 110 transmitting signals (for example, SSBs, CSI-RSs, or other signals) via respective beams (for example, of the beams 160a of the network node 110) and the UE 120 receiving and measuring the signal(s) via respective beams of multiple beams (for example, from the beams 160b of the UE 120) to identify a best beam (or beam pair) for communication between the UE 120 and the network node 110. For example, the UE 120 may transmit an indication (for example, in a message associated with a random access channel (RACH) operation) of a (best) identified beam of the network node 110 (for example, by indicating an SSBRI or other identifier associated with the beam). A beam refinement operation may involve a first device (for example, the UE 120 or the network node 110) transmitting signal(s) via a subset of beams (for example, identified based on, or otherwise associated with, measurements reported as part of one or more other beam management operations). A second device (for example, the network node 110 or the UE 120) may receive the signal(s) via a single beam (for example, to identify the best beam for communication from the subset of beams). The beam(s) may be identified via one or more spatial parameters, such as a transmission configuration indicator (TCI) state and/or a quasi co-location (QCL) parameter, among other examples. The network node 110 and the UE 120 may increase reliability and/or achieve efficiencies in throughput, signal strength, and/or other signal properties for massive MIMO operations by performing the beam management operations.

Some aspects and techniques as described herein may be implemented, at least in part, using an artificial intelligence (AI) program (for example, referred to herein as an “AI/ML model”), such as a program that includes a machine learning (ML) model and/or an artificial neural network (ANN) model. The AI/ML model may be deployed at one or more devices 165 (for example, one or more network nodes 110, one or more UEs 120, and/or one or more servers, and/or one or more components of a cloud computing network, among other examples). For example, in an deployment where AI/ML functionality is performed independently at a device 165, sometimes referred to as “overlay AI/ML”, the AI/ML model (or an instance or portion of the AI/ML model) may be deployed at a UE 120 (for example, at the processing system 140), a network node 110 (for example, at the processing system 145), one or more servers, and/or one or more components of a cloud computing network, among other examples. Additionally, or alternatively, in a deployment where AI/ML functionality is coordinated between different devices 165, sometimes referred to as “coordinated AI/ML”, or performed at all device and network layers, sometimes referred to as “native AI/ML”, the AI/ML model (or an instance of the AI/ML model) may be deployed at multiple devices 165 (for example, a first portion of the AI/ML model may be deployed at a UE 120 and a second portion of the AI/ML model may be deployed at a network node 110). In other examples of coordinated AI/ML and/or native AI/ML, a first AI/ML model may be deployed at a UE 120 and a second AI/ML model may be deployed at a network node 110. The AI/ML model(s) may be configured to enhance various aspects of the wireless communication network 100 (for example, to increase privacy, reliability, and/or efficient use of network bandwidth, and/or to reduce latency, among other examples). For example, the AI/ML model(s) may be trained to identify patterns or relationships in data corresponding to the wireless communication network 100, a device, and/or an air interface, among other examples. The AI/ML model(s) may support operational decisions relating to one or more aspects associated with wireless communications devices, networks, or services.

Accordingly, in some examples, the AI/ML model(s) may enable AI-as-a-Service (for example, an end-to-end AI/ML service via a user plane) for use cases such as a self-organizing network (SON), minimization of drive test (MDT), quality of experience (QoE), positioning, sensing, predictive mobility, and/or traffic prediction, among other examples. In some examples, AI-as-a-Service use cases may include measurement collection reporting by a UE 120, device selection criteria (for example, according to a geographical area where measurements are to be collected and/or UE capabilities to be used to collected measurements), and/or reporting configurations (for example, reporting parameters such as location, time, and/or sensor information, among other examples). Additionally, or alternatively, the AI/ML model(s) may enable AI/ML procedures (for example, RAN-triggered service establishment, configuration, inferencing using UE-side and/or network-side models, performance monitoring and/or management, and/or capability signaling, among other examples). Additionally, or alternatively, the AI/ML model(s) may enable RAN-based AI/ML services via one or more application program interfaces (APIs) and/or management interfaces for use cases such as beam management, radio resource monitoring (RRM) relaxation, mobility prediction, load prediction, network energy savings, and/or coverage and capacity improvements, among other examples.

In the wireless communication network 100, information may be represented as a sequence of binary bits that are mapped (for example, modulated) to an analog signal waveform that is transmitted to a receiver over a wireless communication channel. In some cases, however, the wireless communication channel may introduce errors that corrupt the transmitted signal due to random noise, interference, device impairments, and/or other factors. At the receiver, the received signal (that may have been corrupted during transmission) is mapped back to binary bits, with the received binary information estimating the transmitted binary information. Accordingly, because errors may corrupt the signal that is estimated at the receiver, channel coding or FEC techniques are often used to control errors in data transmission over unreliable or noisy communication channels or otherwise mitigate the bit errors that may occur due to noise, interference, and/or other factors. For example, channel coding generally includes an encoding operation performed at a transmitter (for example, a wireless communication device, which may be a UE 120 or a network node 110) and a decoding operation performed at a receiver (for example, a second wireless device, which may be a UE 120 or a network node 110). Channel coding is generally accomplished by selectively introducing redundancy into the transmitted information stream, typically using an ECC, which allows the receiver to detect errors and/or correct bit errors in the received data stream and thereby provide more reliable information transmission.

Accordingly, channel codes are often used in scenarios where retransmissions are undesirable and/or high transmission reliability is needed, such as downlink and/or uplink control channel communications.

For example, in some cases, the wireless communication network 100 may use polar codes to implement channel coding for downlink and/or uplink control channel communications. More particularly, polar coding is a linear block coding technique that has provable capacity-achieving performance over binary channels with polynomial complexity in various scenarios (such as channel coding, among others). Polar coding has a built-in channel polarization structure that uses a recursive construction to split (or “polarize”) a communication channel into reliable subchannels that are very good for transmitting information and unreliable subchannels that are very bad for transmitting information. The reliable subchannels may be almost completely noiseless, with a capacity that approaches 1, and the unreliable subchannels may be almost completely noisy, with a capacity that approaches 0. During polar encoding, a polar transform is applied to assign information bits to the reliable subchannels and to assign “frozen” or “fixed” bits (for example, “0” bits) to the unreliable subchannels. For example, a polar code with a rate R=K/N may be defined according to a set of parameters {N, K, G_{N}, A}, where N is a code block length with N=2ⁿ, for n≥1, K is a code dimension, A is a data index set, A⊂{1, 2, . . . , N} with size |A|=K, and G_{N} is a polar transform defined by:

$${G}_{2} = [ \begin{matrix}1 & 0 \\ 1 & 1\end{matrix} ] , {G}_{N} = [ \begin{matrix}{G}_{N / 2} & 0 \\ {G}_{N / 2} & {G}_{N / 2}\end{matrix} ] = {G}_{2}^{⊗ n}$$

Given a data block d=(d₁, . . . , d_{K}), a polar code with the parameters {N, K, G_{N}, A} encodes the data block d in two steps, where the first step is to construct a transform input block u=(u₁, . . . , u_{N}) by setting:

$${u}_{A} \hat{=} ( {u}_{i} : i ∈ A ) = d , {u}_{{A}^{C}} \hat{=} ( {u}_{i} : i ∈ {A}^{C} ) = 0$$

and the second step is to compute the code block x by computing the polar transform of u, where x=uG_{N}. Accordingly, polar codes have an encoding/decoding complexity given by N log N, a construction complexity that is roughly O(N), and a block error probability that approaches zero roughly as 2^{-\sqrt{N} for any fixed rate R that is less than a channel capacity (for example, there is no error floor).}

In some aspects, a wireless communication device may correspond to a UE 120 or a network node 110. In particular, the wireless communication device may include a communication manager 150 or a communication manager 155. As described in more detail elsewhere herein, the communication manager 150 or the communication manager 155 may transmit or receive control signaling indicating a configuration for a communication; select one of a uniform polar code sequence or a nonuniform polar code sequence based at least in part on the configuration for the communication; derive, based at least in part on a polar code sequence that is selected, a polar code for encoding a plurality of bits to generate a polar codeword for the communication; encode the plurality of bits using the polar code to generate the polar codeword; and transmit the polar codeword within the communication. Additionally, and as described in more detail elsewhere herein, the communication manager 150 or the communication manager 155 may transmit or receive control signaling indicating a configuration for a communication; receive the communication based at least in part on the configuration, wherein the communication comprises a polar codeword; select one of a uniform polar code sequence or a nonuniform polar code sequence based at least in part on the configuration for the communication; derive, based at least in part on a polar code sequence that is selected, a polar code for decoding the polar codeword to obtain a plurality of bits; and decode the polar codeword using the polar code to obtain the plurality of bits. Additionally, or alternatively, the communication manager 150 or the communication manager 155 may perform one or more other operations described herein.

FIG. 2 is a diagram illustrating an example disaggregated network node architecture 200, in accordance with the present disclosure. One or more components of the example disaggregated network node architecture 200 may be, may include, or may be included in one or more network nodes (such one or more network nodes 110). The disaggregated network node architecture 200 may include a CU 210 that can communicate directly with a core network 220 via a backhaul link, or that can communicate indirectly with the core network 220 via one or more disaggregated control units, such as a non-real-time (Non-RT) RAN intelligent controller (RIC) 250 associated with a Service Management and Orchestration (SMO) Framework 260 and/or a near-real-time (Near-RT) RIC 270 (for example, via an E2 link). The CU 210 may communicate with one or more DUs 230 via respective midhaul links, such as via F1 interfaces. Each of the DUs 230 may communicate with one or more RUs 240 via respective fronthaul links. Each of the RUs 240 may communicate with one or more UEs 120 via respective RF access links. In some deployments, a UE 120 may be simultaneously served by multiple RUs 240.

Each of the components of the disaggregated network node architecture 200, including the CUs 210, the DUs 230, the RUs 240, the Near-RT RICs 270, the Non-RT RICs 250, and the SMO Framework 260, may include one or more interfaces or may be coupled with one or more interfaces for receiving or transmitting signals, such as data or information, via a wired or wireless transmission medium.

In some aspects, the CU 210 may be logically split into one or more CU user plane (CU-UP) units and one or more CU control plane (CU-CP) units. A CU-UP unit may communicate bidirectionally with a CU-CP unit via an interface, such as the E1 interface when implemented in an O-RAN configuration. The CU 210 may be deployed to communicate with one or more DUs 230, as necessary, for network control and signaling. Each DU 230 may correspond to a logical unit that includes one or more base station functions to control the operation of one or more RUs 240. For example, a DU 230 may host various layers, such as an RLC layer, a MAC layer, or one or more PHY layers, such as one or more high PHY layers or one or more low PHY layers. Each layer (which also may be referred to as a module) may be implemented with an interface for communicating signals with other layers (and modules) hosted by the DU 230, or for communicating signals with the control functions hosted by the CU 210. Each RU 240 may implement lower layer functionality. In some aspects, real-time and non-real-time aspects of control and user plane communication with the RU(s) 240 may be controlled by the corresponding DU 230.

The SMO Framework 260 may support RAN deployment and provisioning of non-virtualized and virtualized network elements. For non-virtualized network elements, the SMO Framework 260 may support the deployment of dedicated physical resources for RAN coverage requirements, which may be managed via an operations and maintenance interface, such as an O1 interface. For virtualized network elements, the SMO Framework 260 may interact with a cloud computing platform (such as an open cloud (O-Cloud) platform 290) to perform network element life cycle management (such as to instantiate virtualized network elements) via a cloud computing platform interface, such as an O2 interface. A virtualized network element may include, but is not limited to, a CU 210, a DU 230, an RU 240, a non-RT RIC 250, and/or a Near-RT RIC 270. In some aspects, the SMO Framework 260 may communicate with a hardware aspect of a 4G RAN, a 5G NR RAN, and/or a 6G RAN, such as an open eNB (O-eNB) 280, via an O1 interface. Additionally, or alternatively, the SMO Framework 260 may communicate directly with each of one or more RUs 240 via a respective O1 interface. In some deployments, this configuration can enable each DU 230 and the CU 210 to be implemented in a cloud-based RAN architecture, such as a vRAN architecture.

The Non-RT RIC 250 may include or may implement a logical function that enables non-real-time control and optimization of RAN elements and resources, AI/ML workflows including model training and updates, and/or policy-based guidance of applications and/or features in the Near-RT RIC 270. The Non-RT RIC 250 may be coupled to or may communicate with (such as via an A1 interface) the Near-RT RIC 270. The Near-RT RIC 270 may include or may implement a logical function that enables near-real-time control and optimization of RAN elements and resources via data collection and actions via an interface (such as via an E2 interface) connecting one or more CUs 210, one or more DUs 230, and/or an O-eNB 280 with the Near-RT RIC 270.

In some aspects, to generate AI/ML models to be deployed in the Near-RT RIC 270, the Non-RT RIC 250 may receive parameters or external enrichment information from external servers. Such information may be utilized by the Near-RT RIC 270 and may be received at the SMO Framework 260 or the Non-RT RIC 250 from non-network data sources or from network functions. In some examples, the Non-RT RIC 250 or the Near-RT RIC 270 may tune RAN behavior or performance. For example, the Non-RT RIC 250 may monitor long-term trends and patterns for performance and may employ AI/ML models to perform corrective actions via the SMO Framework 260 (such as reconfiguration via an O1 interface) or via creation of RAN management policies (such as A1 interface policies).

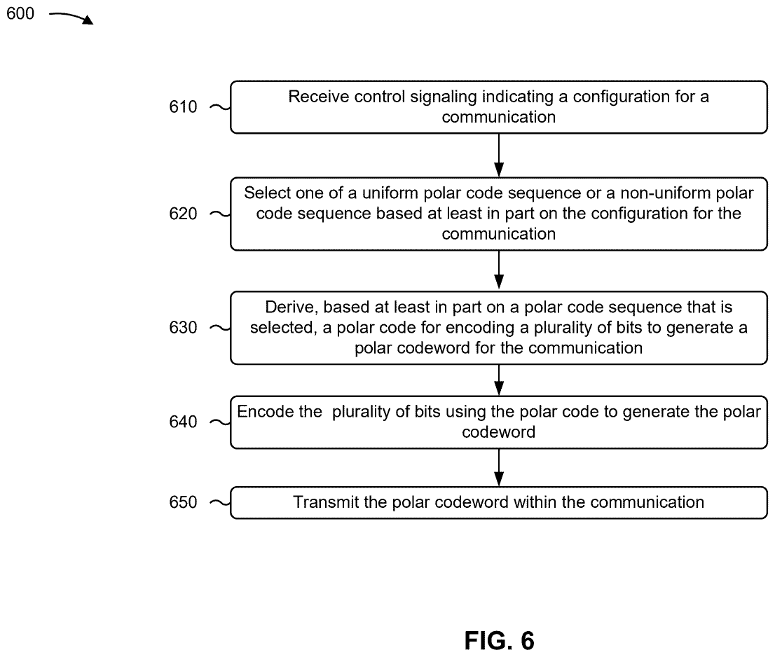

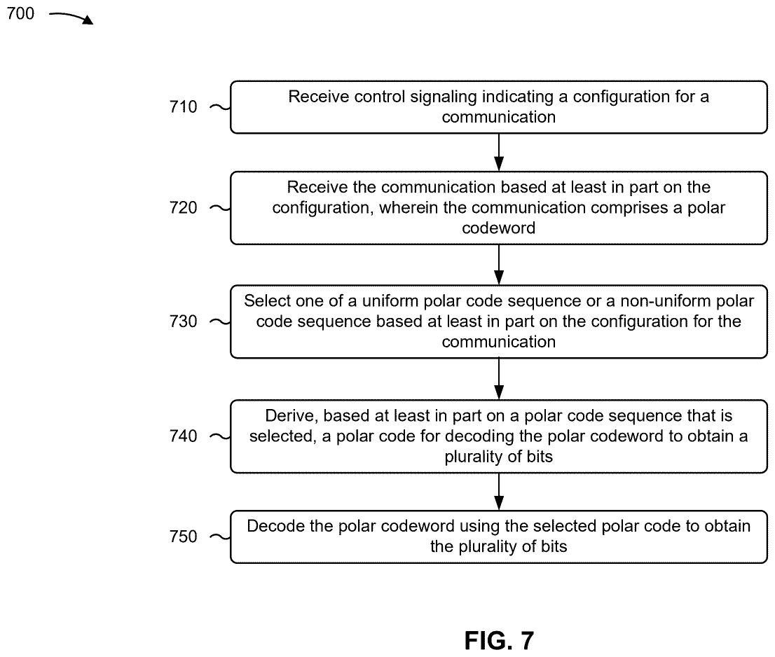

The network node 110, the processing system 145 of the network node 110, the UE 120, the processing system 140 of the UE 120, the CU 210, the DU 230, the RU 240, or any other component(s) of FIG. 1 and/or FIG. 2 may implement one or more techniques or perform one or more operations associated with multiple polar coding sequences, as described in more detail elsewhere herein. In some cases, the wireless communication device described herein may be the UE 120, may be included in the UE 120, may include one or more components of the UE 120, may be the network node 110, may be included in the network node 110, or may include one or more components of the network node 110 shown in FIG. 1. For example, the processing system 145 of the network node 110, the processing system 140 of the UE 120, the CU 210, the DU 230, or the RU 240 may perform or direct operations of, for example, process 600 of FIG. 6, process 700 of FIG. 7, or other processes as described herein (alone or in conjunction with one or more other processors). Memory of the network node 110 may store data and program code (or instructions) for the network node 110, the CU 210, the DU 230, or the RU 240. In some examples, the memory of the network node 110 may store data relating to a UE 120, such as RRC state information or a UE context. Memory of a UE 120 may store data and program code (or instructions) for the UE 120, such as context information. In some examples, the memory of the UE 120 or the memory of the network node 110 may include a non-transitory computer-readable medium storing a set of instructions for wireless communication. For example, the set of instructions, when executed by one or more processors (for example, of the processing system 145 or the processing system 140) of the network node 110, the UE 120, the CU 210, the DU 230, or the RU 240, may cause the one or more processors to perform process 600 of FIG. 6, process 700 of FIG. 7, or other processes as described herein. In some examples, executing instructions may include running the instructions, converting the instructions, compiling the instructions, and/or interpreting the instructions, among other examples.

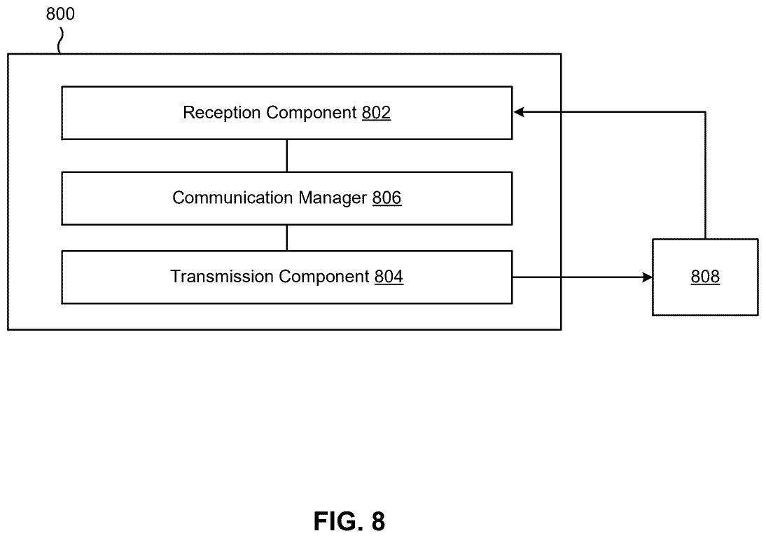

In some aspects, the wireless communication device (e.g., corresponding to a UE 120, a network node 110, or another wireless communication device) includes means for transmitting or receiving control signaling indicating a configuration for a communication; means for selecting one of a uniform polar code sequence or a nonuniform polar code sequence based at least in part on the configuration for the communication; means for deriving, based at least in part on a polar code sequence that is selected, a polar code for encoding a plurality of bits to generate a polar codeword for the communication; means for encoding the plurality of bits using the polar code to generate the polar codeword; and/or means for transmitting the polar codeword within the communication. In some other aspects, the wireless communication device includes means for receiving control signaling indicating a configuration for a communication; means for receiving the communication based at least in part on the configuration, wherein the communication comprises a polar codeword; means for selecting one of a uniform polar code sequence or a nonuniform polar code sequence based at least in part on the configuration for the communication; means for deriving, based at least in part on a polar code sequence that is selected, a polar code for decoding the polar codeword to obtain a plurality of bits; and/or means for decoding the polar codeword using the polar code to obtain the plurality of bits. In some aspects, the means for the wireless communication device to perform operations described herein may include, for example, one or more of communication manager 155, processing system 145, a radio, one or more RF chains, one or more transceivers, one or more antennas, one or more modems, a reception component (for example, reception component 802 depicted and described in connection with FIG. 8), and/or a transmission component (for example, transmission component 804 depicted and described in connection with FIG. 8), among other examples. In some aspects, the means for the wireless communication device to perform operations described herein may include, for example, one or more of communication manager 150, processing system 140, a radio, one or more RF chains, one or more transceivers, one or more antennas, one or more modems, a reception component (for example, reception component 802 depicted and described in connection with FIG. 8), and/or a transmission component (for example, transmission component 804 depicted and described in connection with FIG. 8), among other examples.

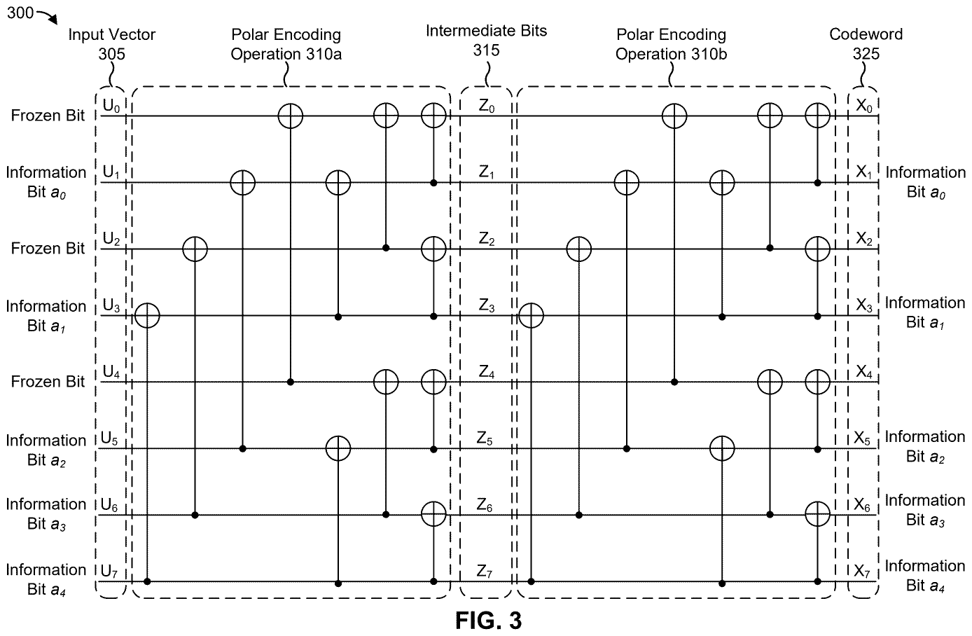

FIG. 3 is a diagram illustrating an example of a systematic polar encoding operation 300 in accordance with the present disclosure. In some cases, a transmitting wireless communication device (such as a UE 120 or a network node 110) may perform the systematic polar encoding operation 300 to generate a systematically polar encoded codeword 325.

In this example, the systematic polar encoding operation 300 is an 8-bit encoding operation, and therefore receives a source (e.g., a set of bits) corresponding to an input vector 305 having a length N=8. Using this information, the systematic polar encoding operation 300 outputs an 8-bit codeword X ([X₀, X₁, . . . , X₇]). Systematic polar encoders of other bit sizes may also be used and in some cases, the output codeword 325 may have a different length than that of the input vector 305.

In the example systematic polar encoding operation 300, the input vector 305 may include a plurality of bits to be encoded, at least a portion of which may be information bits. For example, the information bit a₀ is input to the bit channel U₁, the information bit a₁ is input to the bit channel U₃, the information bit a₂ is input to the bit channel U₅, the information bit a₃ is input to the bit channel U₆, and the information bit a₄ is input to the bit channel U₇. The bit channels U that do not receive an information bit input may receive a frozen bit input. Frozen bits may be specific bits in an encoded codeword (such as the codeword 325) or that are input to a polar encoding operation (such as the first polar encoding operation 310a or the second polar encoding operation 310b) that are set to a fixed value during the encoding process. That is, frozen bits may not carry information and may be reserved for error correction or detection. The frozen bits may, in some cases, be set to ‘0’ or some other predetermined value. In some cases, the bit channels U that are associated with a lower reliability may receive a frozen bit input.

As shown, the bit channel U₀ may receive a frozen bit, and three Boolean exclusive or (XOR) operations are performed (represented by “+” symbol), and bit Z₀ of the intermediate bits 315 is obtained. As depicted, the systematic polar encoding operation 300 may perform zero or more operations on the bits input into each bit channel instance U₀ to U₇. Encoding a bit in one channel instance may depend on bits input to one or more other channel instances. For example, the bit channel U₆ encodes the information bit a₃ by XOR'ing the information bits a₃ an a₄ (Z₆=a₃ XOR a₄).

In some cases, the bit channel instances U_{N} (U₀-U₇) may each have an associated reliability metric. Thus, the information bits assigned bit locations U₀ to U₇ may have varying probabilities of successful decoding once the codeword 325 is transmitted and received at a receiver. In such cases, the input bits input to the ‘k’ most reliable channel instances may be assigned an information bit type.

To perform the example systematic polar encoding operation 300, a device (such as a transmitting device or an encoding device) may perform, in accordance with a polar matrix, a first polar encoding operation 310a on a set of information bits input to a subset of the bit channels U ([U₁, U₂, . . . . U₇]) of the systematic polar encoding operation 300 to obtain a set of intermediate bits 315 that include Z ([Z₁, Z₂, . . . , Z₇]) and performing, in accordance with the polar matrix, a second polar encoding operation 310b on the set of intermediate bits 315 to obtain the codeword 325. That is, the device may perform the systematic polar encoding operation 300 by performing a non-systematic polar encoding operation twice (such as the polar encoding operation 310a and the polar encoding operation 310b). In the example systematic polar encoding operation 300, the first and second polar encoding operations 310 may be based on the same polar matrix. That is, the systematic polar encoding operation 300 is performed based on the polar transform G (such as the polar transform G that is associated with the first polar encoding operation 310a and the second polar encoding operation 310b). In some cases, the polar transform G may be an involution such that G*G=I, which may cause the resulting codeword 325 to be a systematically polar encoded codeword. As an example, a polar transform Gₘ may be defined according to

$${G}_{m} = {( \begin{matrix}1 & 0 \\ 1 & 1\end{matrix} )}^{⊗ m} .$$

In the example systematic polar encoding operation 300, a location of the systematic bits in the codeword 325 (that correspond to the set of information bits) may be the same as the location of the set of information bits in a U-domain (corresponding to the input vector 305). That is, the systematic bits in the codeword 325 may be within the k most reliable bit channels. Accordingly, the location of the systematic bits in the codeword 325 may be based on the polar sequence design. That is, a polar code sequence (e.g., that is predefined) may indicate a location of the information bits and of the frozen bits associated with the polar encoding operation 300. To decode the systematically polar encoded codeword 325, a receiving device may also perform two polar decoding operations in accordance with the same polar matrix. For example, the receiving device may perform a first polar decoding operation to decode the codeword 325 with a decoder (such as a successive cancellation list (SCL) decoder) and obtain the intermediate bits 315 in the Z domain ([Z₁, Z₂, . . . , Z₇]). Then, the receiving device may convert the intermediate bits 315 to the U domain to obtain the information bits via a second polar decoding operation. In some cases, the receiving device may convert the intermediate bits 315 to the U domain by reencoding the intermediate bits 315 using the polar transform G and then selecting the information bits a₀, . . . , a_{K-1} from the information bit locations in the U domain.

In some cases (such as for uniformly distributed sources), systematic and non-systematic polar codes may be associated with similar block error rates (BLERs). However, for joint source-channel coding, one or more of the systematic bits in the codeword 325 may be biased. In joint source-channel coding, a transmitting wireless communication device may integrate source coding (e.g., to compress or remove redundancy within data) and channel coding (e.g., to include error correction or detection information within the data). As an example of joint source-channel coding, the source may have a conditional nonuniform distribution of symbols (e.g., that is based on additional distribution information about the source) and a receiving wireless communication device may determine the additional distribution information about the source and determine that the additional distribution information causes the probability of each possible symbol occurring to not be equal. That is, joint source-channel coding may cause the source to be nonuniformly distributed.

A probability P of a symbol type occurring in each of the systematic bits when joint source-channel coding is used is not equal (e.g., the probability P of one or more of P₀, . . . , P_{N}≠1/N). For example, if each information bit within the codeword 325 is either a ‘0’ or a ‘1,’ the probability of each information bit

$$( {a}_{i} = 0 ) \neq \frac{1}{2} .$$

In some cases, a bias term (e.g., a log-likelihood ratio bias) associated with a probability P of a symbol type occurring in each of the systematic bits in the log-likelihood ratio domain is expressed as

$$log \frac{P ( {a}_{i} = 0 )}{P ( {a}_{i} = 1 )}$$

and may be added to a channel log-likelihood ratio (e.g., by a receiving wireless communication device) prior to decoding. Additionally, if the systematic bits are punctured, a channel log-likelihood ratio may be 0.

As an example of joint source-channel coding that results in a nonuniform distribution of symbols, additional distribution information related to a reliability of communications (e.g., BLERs) may cause the probability of each symbol for HARQ messages to not be equal. That is, if a communication is associated with a 10% BLER, a HARQ message associated with that communication may have a 10% chance of corresponding to a HARQ NACK indication (e.g., a bit ‘1’) and a 90% chance of corresponding to a HARQ ACK indication (e.g., a bit ‘0’). Accordingly, if a network node transmits five PDSCH transmissions, a UE may provide a five-bit HARQ message based on decoding each of the PDSCH transmissions. Each bit within the five-bit HARQ message may have a 10% chance of being a ‘1’ (e.g., indicating a HARQ NACK) and a 90% chance of being a ‘0’ (e.g., indicating a HARQ ACK) if the BLER associated with PDSCH transmissions is 10%.

Another example of joint source-channel coding that results in a nonuniform distribution of symbols relates to CSI. That is, a distribution of channel state feedback bits may be nonuniform and highly correlated over time. Accordingly, a receiving device may determine that some bits are more likely based on previously-received bits within the CSI. Data communications associated with semantic data communication (e.g., for transmission of speech or images) may be associated with residual redundancy, which may correspond to additional distribution information that results in some symbols being more likely within the data communication payload.

The additional bias (e.g., the log-likelihood ratio bias) may result in the channel capacities (e.g., the bit-channel capacities) associated with the polar code sequence. In some cases, the polar code sequence (e.g., the polar code sequence indicative of the frozen and information bit locations for the polar encoding operation) may not enable a transmitting wireless communication device to utilize the different channel capacities to improve an efficiency of communications. That is, polar code sequences that are designed for uniformly distributed payloads may become increasingly suboptimal (e.g., increasingly inefficient) as the source becomes increasingly biased (e.g., less uniform, more nonuniform).

In examples described herein, a transmitting wireless device may support multiple polar code sequences for wireless communications. That is, a transmitting wireless communication device may select a polar code sequence for encoding a set of bits from a uniform polar code sequence (e.g., a polar code sequence that is designed for uniformly distributed sources) and a nonuniform polar code sequence (e.g., a polar code sequence that is designed for nonuniformly distributed sources). In some aspects, a network node may transmit control signaling to a wireless communication device indicating a configuration for a communication. The configuration may indicate to the wireless communication device whether to use the uniform polar code sequence or the nonuniform polar code sequence for encoding or decoding the communication. Then the wireless communication device may use the polar code sequence (e.g., the uniform polar code sequence or the nonuniform polar code sequence) for encoding or decoding the communication in accordance with the configuration.

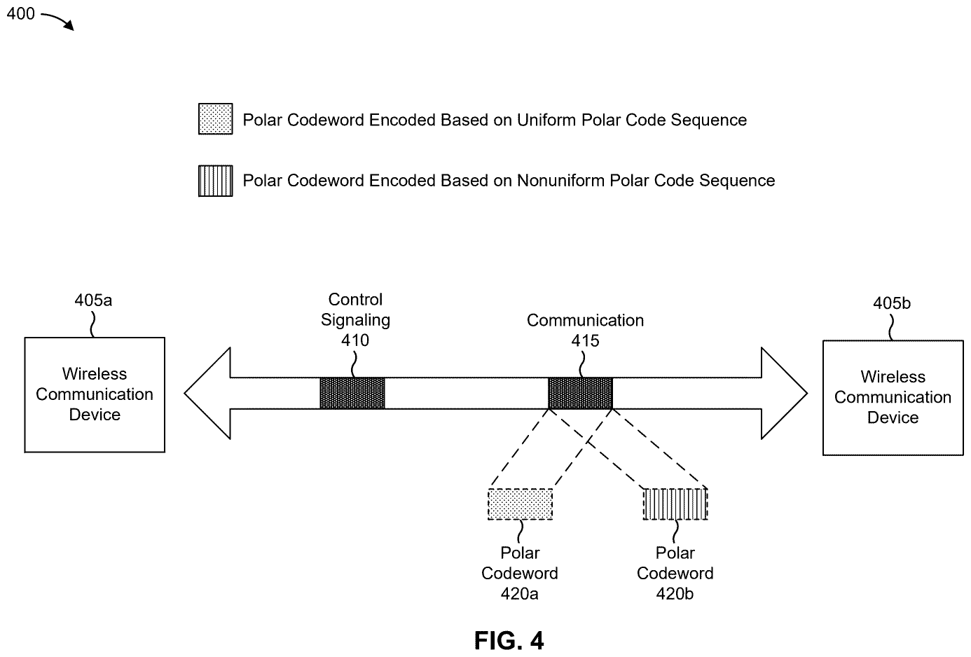

FIG. 4 is a diagram illustrating an example wireless communication network 400, in accordance with the present disclosure. As shown in FIG. 4, the wireless communication device 405a and the wireless communication device 405b may communicate with one another. In particular, the wireless communication devices 405 may be configured to transmit and receive polar codewords 420 that are encoded based on a uniform polar code sequence (e.g., the polar codeword 420a) or based on a nonuniform polar code sequence (e.g., the polar codeword 420b). The wireless communication devices 405 may be network nodes 110, UEs 120, or some other type of wireless communication device. In one example, the wireless communication device 405a may be a network node 110 and the wireless communication device 405b may be a UE 120.

The uniform polar code sequence may be designed for encoding sources (e.g., sets of bits) that are uniformly distributed. Additionally, the uniform polar code sequence may be designed for encoding sources (e.g., sets of bits) that are nonuniformly distributed (such as sources associated with joint source-channel coding). The uniform polar code sequence and the nonuniform polar code sequence may be the same lengths or different lengths. For example, both the uniform and nonuniform polar code sequences may have a length of 512 bits or 1024 bits for a source. In another example, the uniform polar code sequence may be larger than the nonuniform polar code sequence. For example, the uniform polar code sequence may have a length of 1024 bits and the nonuniform polar code sequence may have a length of 512 bits.

The length of the nonuniform polar code sequence may be less than the length of the uniform polar code sequence based on a shorter codeword being sufficient to communicate a source when joint source-channel coding is used (e.g., as compared to when joint source-channel coding is not used). For example, a PDCCH communication that includes a joint source-channel coding codeword may carry a payload within a 512 bit codeword, while a PDCCH communication that does not include a joint source-channel coding codeword may carry the payload within a 1024 bit codeword. In another example, a HARQ message (e.g., a HARQ-ACK or a HARQ-NACK) that includes a joint source-channel coding codeword may carry a payload within a 512 bit codeword, while a HARQ message that does not include a joint source-channel coding codeword may carry the payload within a 1024 bit codeword.

The distribution of information bits indicated by the uniform polar code sequence and the nonuniform polar code sequence may be different. For example, for a given information bit length K and a coded bit length N=2^{m}, the nonuniform polar code sequence may assign more information bits to a second half of the polar code as compared to the uniform polar code sequence. That is, a first quantity of information bit locations included in the second half of a uniform polar code sequence is less than a second quantity of information bit locations included in the second half of a nonuniform polar code sequence of the same length. The bit locations in the first half of a polar code sequence correspond to the half of the bit locations in the polar code sequence that have smaller indices than a remaining portion of the bit locations in the polar code sequence. Additionally, the bit locations in the second half of a polar code sequence correspond to the half of the bit locations in the polar code sequence that have larger indices than a remaining portion of the bit locations in the polar code sequence. As an example, for a rate

$$R = \frac{K}{N} = 1 / 4$$

and a polar code length N=2^{m}=256, a uniform polar code sequence may include two information bits in the first half of bit locations and a nonuniform polar code sequence may include no information bits in the first half of bit locations. Accordingly, the uniform polar code sequence may include two fewer information bits in the second half of the bit locations as compared to the nonuniform polar code sequence.

The wireless communication device 405a may transmit, and the wireless communication device 405b may receive, the control signaling 410. The control signaling 410 may be transmitted via a control channel, such as via a PDCCH. Additionally, or alternatively, the control signaling 410 may correspond to RRC signaling, DCI, or a MAC-CE.

The control signaling 410 may indicate a configuration for a communication 415 (e.g., that includes either the polar codeword 420a or the polar codeword 420b). The communication 415 may correspond to an uplink communication (e.g., transmitted by the wireless communication device 405b to the wireless communication device 405a) or a downlink communication (e.g., transmitted by the wireless communication device 405a to the wireless communication device 405b). In one example, the control signaling 410 may schedule the transmission of the communication 415 that includes the polar codeword 420a or the polar codeword 420b.

Additionally, or alternatively, the control signaling 410 may indicate whether the communication 415 is to include a polar codeword 420 that is encoded using a uniform polar code sequence (e.g., the polar codeword 420a) or that is encoded using a nonuniform polar code sequence (e.g., the polar codeword 420b). That is, a bias of a payload within the communication 415 may be related to a content of the payload within the communication 415. Accordingly, a network entity may configure a wireless communication device (such as the wireless communication device 405b) to encode a polar codeword 420 using a uniform polar code sequence or a nonuniform polar code sequence based on a content of the payload.

The wireless communication device 405a may configure, via the control signaling 410, a type of polar code sequence for encoding for a single communication 415. Additionally, or alternatively, the wireless communication device 405a may configure, via the control signaling 410, a type of polar code sequence for encoding communications based on one or more parameters associated with the communication 415. For example, the wireless communication device 405a may configure the type of polar code sequence for encoding communications based on a format associated with the communication 415 (e.g., a DCI format, a PUCCH format), a resource associated with the communication 415 (e.g., a search space, a control resource set, a PUCCH resource, a PUCCH resource set), a channel associated with the communication (e.g., a PUCCH, a PDCCH, a PBCH) and/or a content of the payload associated with the communication 415 (e.g., whether the communication 415 includes a HARQ message or UCI).

In some cases where the communication 415 is a PDCCH transmission, the wireless communication device 405a may indicate a type of polar code sequence for encoding the communication 415 based on a DCI format of the communication 415, a search space associated with the communication 415, and/or a control resource set associated with the communication 415. That is, the wireless communication device 405a may configure a polar code sequence (e.g., may configure either the uniform polar code sequence or the nonuniform polar code sequence) for each DCI format, search space, and/or control resource set. Then the wireless communication device 405b may select the uniform polar code sequence or the nonuniform polar code sequence for decoding the communication 415 based on the DCI format, search space, and/or control resource set associated with the communication 415. In one example, the wireless communication device 405a may configure the uniform polar code sequence to be used for PDCCH transmissions that are associated with common search spaces and the nonuniform polar code sequence to be used for PDCCH transmissions that are associated with UE-specific search spaces. In another example, the wireless communication device 405a may configure the nonuniform polar code sequence to be used for scheduling DCI formats (e.g., non-fallback uplink and downlink scheduling DCIs) and may configure the uniform polar code sequence to be used for one or more non-scheduling DCI formats and/or fallback scheduling DCI formats.

In some other cases where the communication 415 is a PUCCH transmission, the wireless communication device 405a may indicate a type of polar code sequence for encoding the communication 415 based on a PUCCH format of the communication 415, a PUCCH resource of the communication 415, and/or a PUCCH resource set. That is, the wireless communication device 405a may configure a polar code sequence (e.g., may configure either the uniform polar code sequence or the nonuniform polar code sequence) for each PUCCH format, each PUCCH resource, and/or each PUCCH resource set. Then the wireless communication device 405b may select the uniform polar code sequence or the nonuniform polar code sequence for encoding the communication 415 based on the PUCCH format, the PUCCH resource, and/or the PUCCH resource set associated with the communication 415.

In some cases, the wireless communication device 405a may configure, via the control signaling 410, a polar code sequence for different channel types. For example, the wireless communication device 405a may indicate, from the uniform polar code sequence and the nonuniform polar code sequence, a polar code sequence for encoding or decoding communications associated with a PUCCH, a polar code sequence for encoding or decoding communications associated with a PDCCH, and/or a polar code sequence for encoding or decoding communications associated with a PBCH. Additionally, the wireless communication device 405a may indicate, from the uniform polar code sequence and the nonuniform polar code sequence, a polar code sequence for encoding or decoding communications associated with other channels (such as a PDSCH or a PUSCH). In one example, the wireless communication device 405a may configure the PUCCH and the PDCCH to support communications encoded using both the uniform polar code sequence and the nonuniform polar code sequence and may configure the PBCH to support communications encoded using the uniform polar code sequence (e.g., and to not support communications encoded using the nonuniform polar code sequence).

In some cases, the wireless communication device 405a may configure, via the control signaling 410, a polar code sequence for different types of a payload associated with the communication 415. In one example, the wireless communication device 405a may configure the uniform polar code sequence to be used for every type of payload other than HARQ messages. That is, the wireless communication device 405a may configure the nonuniform polar code sequence to be used for communicating HARQ messages (e.g., HARQ ACK or HARQ NACK communications) and the uniform polar code sequence to be used for other communications.

In another example, the wireless communication device 405a may indicate, from the uniform polar code sequence and the nonuniform polar code sequence, a polar code sequence for encoding or decoding different types of UCI. That is, the wireless communication device 405a may configure a polar code sequence for UCI that is associated with a CSI message (e.g., for UCI having a payload that includes the CSI message), UCI that is associated with a HARQ message (e.g., for UCI having a payload that includes the HARQ message), and UCI that is associated with both a CSI message and a HARQ message. Then the wireless communication device 405b may select the uniform polar code sequence or the nonuniform polar code sequence for encoding the communication 415 based on whether a payload associated with the communication 415 includes a CSI message, a HARQ message, or both. In one example, the wireless communication device 405a may configure the uniform polar code sequence to be used when the payload associated with the communication 415 includes the CSI message and may configure the nonuniform polar code sequence to be used when the payload associated with the communication includes the HARQ message, and may configure either the uniform or nonuniform polar code sequence to be used when the payload is associated with both the CSI message and the HARQ message (e.g., when the HARQ and CSI messages are multiplexed).

Based on the configuration for the communication 415 indicated by the control signaling 410, the wireless communication device 405b may select a polar code sequence, from the uniform polar code sequence and the nonuniform polar code sequence, for deriving a polar code used to encode or decode the communication 415. For example, if the communication 415 corresponds to an uplink communication transmitted from the wireless communication device 405b to the wireless communication device 405a, the wireless communication device 405b may select the polar code sequence. Then the wireless communication device 405b may derive a polar code based on the selected polar code sequence and encode a set of bits (e.g., corresponding to the payload of the communication 415) using the polar code to generate the polar codeword 420a or the polar codeword 420b. That is, if the wireless communication device 405b selects the uniform polar code sequence, the wireless communication device 405b may derive a polar code based on the uniform polar code sequence (e.g., a polar code having information bit locations indicated by the uniform polar code sequence) and generate the polar codeword 420a using the polar code and based on the selected polar code sequence. Additionally, if the wireless communication device 405b selects the nonuniform polar code sequence, the wireless communication device 405b may derive a polar code based on the nonuniform polar code sequence (e.g., a polar code having information bit locations indicated by the nonuniform polar code sequence) and generate the polar codeword 420b using the polar code and based on the selected polar code sequence. The wireless communication device 405b may then transmit the communication 415 to the wireless communication device 405a.

In another example, if the communication 415 correspond to a downlink communication transmitted from the wireless communication device 405a to the wireless communication device 405b, the wireless communication device 405a may select the polar code sequence, from the uniform and nonuniform polar code sequence, for decoding the polar codeword 420 within the communication 415. Then the wireless communication device 405b may derive a polar code for decoding the polar codeword 420 using the selected polar code sequence. That is, if the wireless communication device 405b selects the uniform polar code sequence for the decoding, the wireless communication device 405b may derive the polar code for decoding the polar codeword 420a using the selected polar code sequence. Additionally, if the wireless communication device 405b selects the nonuniform polar code sequence for the decoding, the wireless communication device 405b may derive the polar code for decoding the polar codeword 420b using the selected polar code sequence.

As indicated above, FIG. 4 is provided as an example. Other examples may differ from what is described with respect to FIG. 4.

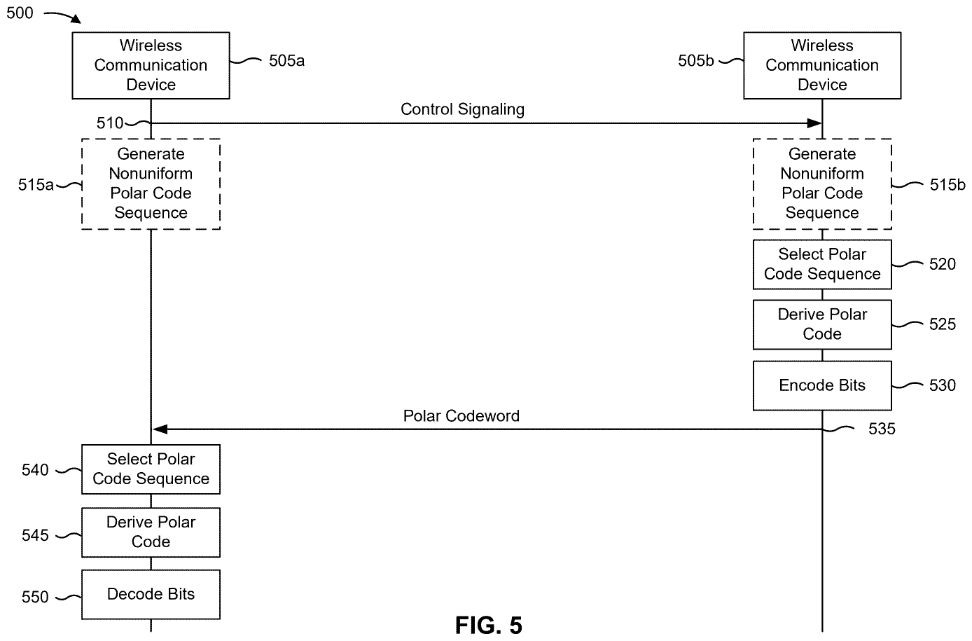

FIG. 5 is a diagram illustrating an example 500 associated with multiple polar code sequences, in accordance with the present disclosure. As shown in FIG. 5, the wireless communication devices 505 may communicate with one another. In particular, the wireless communication devices 505 may be configured to transmit and receive polar codewords that are encoded using a uniform polar code sequence or using a nonuniform polar code sequence. The wireless communication devices 505 may be network nodes 110, UEs 120, or some other type of wireless communication device. In one example, the wireless communication device 505a may be a network node 110 and the wireless communication device 505b may be a UE 120.

At 510, the wireless communication device 505a may transmit, and the wireless communication device 505b may receive, the control signaling. The control signaling may include aspects of the control signaling 410 described with reference to FIG. 4. In particular, the control signaling may indicate a configuration for a communication. For example, the control signaling may indicate a polar code, from a uniform polar code sequence and a nonuniform polar code sequence, for encoding the communication.

At 515a and 515b, the wireless communication devices 505 may optionally generate the nonuniform polar code sequence. That is, in some examples the nonuniform polar code sequence may be predefined or preconfigured. That is, the nonuniform polar code sequence may be defined and known to both the wireless communication device 505a and the wireless communication device 505b. In these examples, the wireless communication devices 505 may not generate the nonuniform polar code sequence at 515. Additionally, if the nonuniform polar code sequence is not predefined, the wireless communication device 505a and/or the wireless communication device 505b may generate the nonuniform polar code sequence.

To generate the nonuniform polar code sequence, the wireless communication device 505a and the wireless communication device 505b may use an iterative procedure to generate the nonuniform polar code sequence from the uniform polar code sequence. For a first iteration, the wireless communication device 505a and the wireless communication device 505b may select the set of K information bit locations associated with the uniform polar code sequence. The wireless communication device 505a and the wireless communication device 505b may then apply, to a first set of channels associated with the set of K information bit locations, a log-likelihood ratio bias to identify a first set of channel capacities (e.g., that are nonuniformly distributed) in the X domain (e.g., as illustrated by the codeword 325 in FIG. 3).

Based on the first set of channel capacities, the wireless communication device 505a and the wireless communication device 505b may identify a second set of information bit locations, which may be different from the first set of information bit locations associated with the uniform polar code sequence based on applying the log-likelihood ratio biases. The wireless communication device 505a and the wireless communication device 505b may identify the second set of information bit locations using a density evolution to propagate the channel capacities from the X domain to the U domain (e.g., as illustrated by the input vector 305 in FIG. 3). Additionally, or alternatively, the wireless communication device 505a and the wireless communication device 505b may identify the second set of information bit locations using a Gaussian approximation to propagate the log-likelihood ratio biases from the X domain to the U domain. Additionally, or alternatively, the wireless communication device 505a and the wireless communication device 505b may use a fractally enhanced kernel (FRANK) procedure to recursively identify the second set of information bit locations.

If the second set of information bit locations is the same as the first set of information bit locations, the polar code sequence associated with the first set of information bit locations (e.g., the uniform polar code sequence) may be efficient for the nonuniformly distributed source. However if the second set of information bit locations is different from the first set of information bit locations, the polar code sequence associated with the second set of information bit locations may be more efficient for the nonuniformly distributed source (e.g., the polar code sequence associated with the first set of information bit locations may not be efficient for the nonuniformly distributed source).

The wireless communication device 505a and the wireless communication device 505b may perform one or more additional iterations (e.g., by applying log-likelihood ratio biases to the information bit locations indicated by an initial set of information bit locations, identifying an updated set of channel capacities, and identifying a subsequent set of information bit locations based on the second set of channel capacities) until a set of information bit locations indicated by an initial polar code sequence is the same as set of information bit locations indicated by a subsequent polar code sequence after the iteration. The initial polar code sequence and the subsequent polar code sequence may indicate the same set of information bit locations after two or three iterations. In some other examples, the wireless communication device 505a and the wireless communication device 505b may generate the nonuniform polar code sequence based on performing a fixed (e.g., predefined, preconfigured) quantity of iterations. For example, the quantity of iterations may be set to one iteration, two iterations, or three iterations. The polar code sequence associated with the information bit locations after performing the iterations may correspond to the nonuniform polar code sequence.

The wireless communication device 505a and the wireless communication device 505b may generate the nonuniform polar code sequence offline (e.g., during a time interval where the wireless communication device 505a or 505b is not communicating with any other wireless communication devices). Then, the wireless communication device 505a and the wireless communication device 505b may store the generated nonuniform polar code sequence. For example, the wireless communication device 505a may store the generated nonuniform polar code sequence within memory at the wireless communication device 505a. Additionally, the wireless communication device 505b may store the generated nonuniform polar code sequence within memory at the wireless communication device 505b.

In some other cases, the wireless communication device 505a and the wireless communication device 505b may generate the nonuniform polar code sequence based on the source (e.g., when the wireless communication device 505a and the wireless communication device 505b are not offline). Here, the generated nonuniform polar code sequence may be based on the source.

At 520, the wireless communication device 505b may select one of the uniform polar code sequence or the nonuniform polar code sequence. That is, the wireless communication device 505b may select either the uniform polar code sequence or the nonuniform polar code sequence for deriving a polar code. The wireless communication device 505b may select the polar code sequence based on the configuration for a communication, which may be indicated to the wireless communication device 505 via the control signaling at 510.

At 525, the wireless communication device 505b may derive a polar code based on the polar code sequence selected at 520. In some cases, the wireless communication device 505b may derive the polar code based on the selected polar code sequence indicating the information bit locations for the polar code. The derived polar code may be for encoding a set of bits (e.g., corresponding to a payload for the communication) to generate a polar codeword for the communication.

At 530, the wireless communication device 505b may encode the set of bits using the polar code to generate a polar codeword. At 535, the wireless communication device 505b may transmit, and the wireless communication device 505a may receive, the polar code within the communication. The polar codeword illustrated at 535 may be an example of the polar codeword 420a or the polar codeword 420b as described with reference to FIG. 4. For example, if the wireless communication device 505b selects the uniform polar code sequence at 520, the polar codeword transmitted at 535 may be an example of the polar codeword 420a. Additionally, if the wireless communication device 505b selects the nonuniform polar code sequence at 520, the polar codeword transmitted at 535 may be an example of the polar codeword 420b.

At 540, the wireless communication device 505a may select a polar code sequence, from the uniform polar code sequence and the nonuniform polar code sequence, for decoding the polar codeword. In some cases, the wireless communication device 505a may select the same type of polar code sequence at 535 as the wireless communication device 505b selects at 520 (e.g., to encode the polar codeword).

At 545, the wireless communication device 505a may derive a polar code based on the polar code sequence selected at 540. In some cases, the wireless communication device 505a may derive the polar code based on the selected polar code sequence indicating the information bit locations for the polar code. The derived polar code may be for decoding the polar codeword to obtain the set of bits (e.g., corresponding to a payload for the communication).

At 550, the wireless communication device 505a may decode the polar codeword using the polar code to obtain the set of bits (e.g., the payload associated with the communication).

As indicated above, FIG. 5 is provided as an example. Other examples may differ from what is described with respect to FIG. 5.

FIG. 6 is a diagram illustrating an example process 600 performed, for example, at a wireless communication device or an apparatus of a wireless communication device, in accordance with the present disclosure. Example process 600 is an example where the apparatus or the wireless communication device (e.g., network node 110, UE 120, wireless communication device 405, wireless communication device 505, the apparatus 800) performs operations associated with multiple polar coding sequences.

As shown in FIG. 6, in some aspects, process 600 may include receiving control signaling indicating a configuration for a communication (block 610). For example, the wireless communication device (e.g., using reception component 802 and/or communication manager 806, depicted in FIG. 8) may receive control signaling indicating a configuration for a communication, as described above. Additionally, or alternatively, the process 600 may include transmitting the control signaling indicating the configuration for the communication (e.g., instead of the receiving of the control signaling illustrated in block 610). For example, the wireless communication device (e.g., using transmission component 804 and/or communication manager 806, depicted in FIG. 8) may transmit control signaling indicating a configuration for a communication, as described above. In some aspects, the receiving or transmitting of the control signaling may be performed in a manner similar to the communication of the control signaling 410 of FIG. 4, and/or the communication of the control signaling at 510 as described with reference to FIG. 5.

As further shown in FIG. 6, in some aspects, process 600 may include selecting one of a uniform polar code sequence or a nonuniform polar code sequence based at least in part on the configuration for the communication (block 620). For example, the wireless communication device (e.g., using communication manager 806, depicted in FIG. 8) may select one of a uniform polar code sequence or a nonuniform polar code sequence based at least in part on the configuration for the communication, as described above. In some aspects, the selecting of the polar code sequence be performed in a manner similar to the selection of the polar code sequence at 520 as described with reference to FIG. 5.

As further shown in FIG. 6, in some aspects, process 600 may include deriving, based at least in part on a polar code sequence that is selected, a polar code for encoding a plurality of bits to generate a polar codeword for the communication (block 630). For example, the wireless communication device (e.g., using communication manager 806, depicted in FIG. 8) may derive, based at least in part on a polar code sequence that is selected, a polar code for encoding a plurality of bits to generate a polar codeword for the communication, as described above. In some aspects, the deriving may be performed in a manner similar to the deriving at 525 as described with reference to FIG. 5.

As further shown in FIG. 6, in some aspects, process 600 may include encoding the plurality of bits using the polar code to generate the polar codeword (block 640). For example, the wireless communication device (e.g., using communication manager 806, depicted in FIG. 8) may encode the plurality of bits using the polar code to generate the polar codeword, as described above. In some aspects, the encoding may be performed in a manner similar to the encoding of bits at 530 as described with reference to FIG. 5.

As further shown in FIG. 6, in some aspects, process 600 may include transmitting the polar codeword within the communication (block 650). For example, the wireless communication device (e.g., using transmission component 804 and/or communication manager 806, depicted in FIG. 8) may transmit the polar codeword within the communication, as described above. In some aspects, the transmitting of the communication may be performed in a manner similar to the transmitting of the polar codeword 420a or the polar codeword 420b of FIG. 4, and/or the transmitting of the codeword by the wireless communication device 505b at 535 as described with reference to FIG. 5.

Process 600 may include additional aspects, such as any single aspect or any combination of aspects described below and/or in connection with one or more other processes described elsewhere herein.

In a first aspect, the configuration indicates the polar code sequence, from the uniform polar code sequence and the nonuniform polar code sequence, for the encoding for the communication (e.g., as described in connection with FIGS. 4 and 5).

In a second aspect, alone or in combination with the first aspect, process 600 includes generating the nonuniform polar code sequence based at least in part on the uniform polar code sequence, wherein the encoding is based at least in part on the generating (e.g., as described in connection with FIGS. 4 and 5).

In a third aspect, alone or in combination with one or more of the first and second aspects, the generating comprises applying, to a first plurality of channels associated with a first plurality of information bit locations of the uniform polar code sequence, a log-likelihood ratio bias to identify a first plurality of channel capacities; and identifying, based at least in part on the first plurality of channel capacities, a second plurality of information bit locations associated with the nonuniform polar code sequence (e.g., as described in connection with FIGS. 4 and 5).

In a fourth aspect, alone or in combination with one or more of the first through third aspects, process 600 includes storing the nonuniform polar code sequence at the wireless communication device, wherein the selecting is based at least in part on the storing (e.g., as described in connection with FIGS. 4 and 5).

In a fifth aspect, alone or in combination with the first aspect, the uniform polar code sequence and the nonuniform polar code sequence are predefined (e.g., as described in connection with FIGS. 4 and 5).

In a sixth aspect, alone or in combination with one or more of the first through fifth aspects, process 600 includes the uniform polar code sequence is associated with polar encoding uniformly distributed bits, and the nonuniform polar code sequence is associated with polar encoding nonuniformly distributed bits (e.g., as described in connection with FIGS. 4 and 5).

In a seventh aspect, alone or in combination with one or more of the first through sixth aspects, the uniform polar code sequence comprises a first subset of bit locations in the uniform polar code sequence that comprises a first half of the bit locations in the uniform polar code sequence that have larger indices than a second half of the bit locations in the uniform polar code sequence, the nonuniform polar code sequence comprises a second subset of bit locations in the nonuniform polar code sequence that comprises a first half of the bit locations in the nonuniform polar code sequence that have larger indices than a second half of the bit locations in the nonuniform polar code sequence, and a first quantity of information bit locations in the first subset of bit locations in the uniform polar code sequence is less than a second quantity of information bit locations in the second subset of bit locations in the nonuniform polar code sequence (e.g., as described in connection with FIGS. 4 and 5).

In an eighth aspect, alone or in combination with one or more of the first through seventh aspects, a first size of the uniform polar code sequence is different from a second size of the nonuniform polar code sequence (e.g., as described in connection with FIGS. 4 and 5).

In a ninth aspect, alone or in combination with one or more of the first through eighth aspects, the first size is greater than the second size (e.g., as described in connection with FIGS. 4 and 5).

In a tenth aspect, alone or in combination with one or more of the first through ninth aspects, the configuration indicates the polar code sequence, from the uniform polar code sequence and the nonuniform polar code sequence, for the communication based at least in part on a downlink control information format of the communication, a search space associated with the communication, or a control resource set associated with the communication (e.g., as described in connection with FIGS. 4 and 5).

In an eleventh aspect, alone or in combination with one or more of the first through tenth aspects, the configuration indicates the polar code sequence, from the uniform polar code sequence and the nonuniform polar code sequence, for the communication based at least in part on PUCCH format associated with the communication, a PUCCH resource associated with the communication, or a PUCCH resource set associated with the communication (e.g., as described in connection with FIGS. 4 and 5).

In a twelfth aspect, alone or in combination with one or more of the first through eleventh aspects, the configuration indicates the polar code sequence, from the uniform polar code sequence and the nonuniform polar code sequence, for the communication based at least in part on a channel type associated with the communication (e.g., as described in connection with FIGS. 4 and 5).

In a thirteenth aspect, alone or in combination with one or more of the first through twelfth aspects, the channel type associated with the communication is a PUCCH, a PDCCH, or a PBCH (e.g., as described in connection with FIGS. 4 and 5).

In a fourteenth aspect, alone or in combination with one or more of the first through thirteenth aspects, the configuration indicates the polar code sequence, from the uniform polar code sequence and the nonuniform polar code sequence, for the communication based at least in part on a type of UCI associated with the communication (e.g., as described in connection with FIGS. 4 and 5).

In a fifteenth aspect, alone or in combination with one or more of the first through fourteenth aspects, the type of UCI associated with the communication is a HARQ message, a CSI message, or both (e.g., as described in connection with FIGS. 4 and 5).

In a sixteenth aspect, alone or in combination with one or more of the first through fifteenth aspects, the control signaling comprises RRC signaling or a MAC-CE (e.g., as described in connection with FIGS. 4 and 5).

Although FIG. 6 shows example blocks of process 600, in some aspects, process 600 may include additional blocks, fewer blocks, different blocks, or differently arranged blocks than those depicted in FIG. 6. Additionally, or alternatively, two or more of the blocks of process 600 may be performed in parallel.

FIG. 7 is a diagram illustrating an example process 700 performed, for example, at a wireless communication device or an apparatus of a wireless communication device, in accordance with the present disclosure. Example process 700 is an example where the apparatus or the wireless communication device (e.g., network node 110, UE 120, wireless communication device 405, wireless communication device 505, the apparatus 800) performs operations associated with multiple polar coding sequences.

As shown in FIG. 7, in some aspects, process 700 may include receiving control signaling indicating a configuration for a communication (block 710). For example, the wireless communication device (e.g., using reception component 802 and/or communication manager 806, depicted in FIG. 8) may receive control signaling indicating a configuration for a communication, as described above. Additionally, or alternatively, the process 700 may include transmitting the control signaling indicating the configuration for the communication (e.g., instead of the receiving of the control signaling illustrated in block 710). For example, the wireless communication device (e.g., using transmission component 804 and/or communication manager 806, depicted in FIG. 8) may transmit control signaling indicating a configuration for a communication, as described above. In some aspects, the receiving or transmitting of the control signaling may be performed in a manner similar to the communication of the control signaling 410 of FIG. 4, and/or the communication of the control signaling at 510 as described with reference to FIG. 5.

As further shown in FIG. 7, in some aspects, process 700 may include receiving the communication based at least in part on the configuration, wherein the communication comprises a polar codeword (block 720). For example, the wireless communication device (e.g., using reception component 802 and/or communication manager 806, depicted in FIG. 8) may receive the communication based at least in part on the configuration, wherein the communication comprises a polar codeword, as described above. In some aspects, the receiving of the communication may be performed in a manner similar to the receiving of the polar codeword 420a or the polar codeword 420b of FIG. 4, and/or the receiving of the codeword by the wireless communication device 505a at 535 as described with reference to FIG. 5.

As further shown in FIG. 7, in some aspects, process 700 may include selecting one of a uniform polar code sequence or a nonuniform polar code sequence based at least in part on the configuration for the communication (block 730). For example, the wireless communication device (e.g., using communication manager 806, depicted in FIG. 8) may select one of a uniform polar code sequence or a nonuniform polar code sequence based at least in part on the configuration for the communication, as described above. In some aspects, the selecting of the polar code sequence may be performed in a manner similar to the selection of the polar code at 540 as described with reference to FIG. 5.

As further shown in FIG. 7, in some aspects, process 700 may include deriving, based at least in part on a polar code sequence that is selected, a polar code for decoding the polar codeword to obtain a plurality of bits (block 740). For example, the wireless communication device (e.g., using communication manager 806, depicted in FIG. 8) may derive, based at least in part on a polar code sequence that is selected, a polar code for decoding the polar codeword to obtain a plurality of bits, as described above. In some aspects, the deriving may be performed in a manner similar to the deriving at 545 as described with reference to FIG. 5.

As further shown in FIG. 7, in some aspects, process 700 may include decoding the polar codeword using the selected polar code to obtain the plurality of bits (block 750). For example, the wireless communication device (e.g., using communication manager 806, depicted in FIG. 8) may decode the polar codeword using the polar code to obtain the plurality of bits, as described above. In some aspects, the encoding may be performed in a manner similar to the decoding of bits at 550 as described with reference to FIG. 5.

Process 700 may include additional aspects, such as any single aspect or any combination of aspects described below and/or in connection with one or more other processes described elsewhere herein.

In a first aspect, the configuration indicates the polar code sequence, from the uniform polar code sequence and the nonuniform polar code sequence, for the decoding for the communication (e.g., as described in connection with FIGS. 4 and 5).

In a second aspect, alone or in combination with the first aspect, process 700 includes generating the nonuniform polar code sequence based at least in part on the uniform polar code sequence, wherein the decoding is based at least in part on the generating (e.g., as described in connection with FIGS. 4 and 5).

In a third aspect, alone or in combination with one or more of the first and second aspects, the generating comprises applying, to a first plurality of channels associated with a first plurality of information bit locations of the uniform polar code sequence, a log-likelihood ratio bias to identify a first plurality of channel capacities, and identifying, based at least in part on the first plurality of channel capacities, a second plurality of information bit locations associated with the nonuniform polar code sequence (e.g., as described in connection with FIGS. 4 and 5).

In a fourth aspect, alone or in combination with one or more of the first through third aspects, process 700 includes storing the nonuniform polar code sequence at the wireless communication device, wherein the selecting is based at least in part on the storing (e.g., as described in connection with FIGS. 4 and 5).

In a fifth aspect, alone or in combination with one or more of the first aspect, the uniform polar code sequence and the nonuniform polar code sequence are predefined (e.g., as described in connection with FIGS. 4 and 5).

In a sixth aspect, alone or in combination with one or more of the first through fifth aspects, process 700 includes the uniform polar code sequence is associated with polar decoding uniformly distributed bits, and the nonuniform polar code sequence is associated with polar decoding nonuniformly distributed bits (e.g., as described in connection with FIGS. 4 and 5).

In a seventh aspect, alone or in combination with one or more of the first through sixth aspects, the uniform polar code sequence comprises a first subset of bit locations in the uniform polar code sequence that comprises a first half of the bit locations in the uniform polar code sequence that have larger indices than a second half of the bit locations in the uniform polar code sequence, the nonuniform polar code sequence comprises a second subset of bit locations in the nonuniform polar code sequence that comprises a first half of the bit locations in the nonuniform polar code sequence that have larger indices than a second half of the bit locations in the nonuniform polar code sequence, and a first quantity of information bit locations in the first subset of bit locations in the uniform polar code sequence is less than a second quantity of information bit locations in the second subset of bit locations in the nonuniform polar code sequence (e.g., as described in connection with FIGS. 4 and 5).

In an eighth aspect, alone or in combination with one or more of the first through seventh aspects, a first size of the uniform polar code sequence is different from a second size of the nonuniform polar code sequence (e.g., as described in connection with FIGS. 4 and 5).

In a ninth aspect, alone or in combination with one or more of the first through eighth aspects, the first size is greater than the second size (e.g., as described in connection with FIGS. 4 and 5).

In a tenth aspect, alone or in combination with one or more of the first through ninth aspects, the configuration indicates the polar code sequence, from the uniform polar code sequence and the nonuniform polar code sequence, for the communication based at least in part on a downlink control information format of the communication, a search space associated with the communication, or a control resource set associated with the communication (e.g., as described in connection with FIGS. 4 and 5).

In an eleventh aspect, alone or in combination with one or more of the first through tenth aspects, the configuration indicates the polar code sequence, from the uniform polar code sequence and the nonuniform polar code sequence, for the communication based at least in part on PUCCH format associated with the communication, a PUCCH resource associated with the communication, or a PUCCH resource set associated with the communication (e.g., as described in connection with FIGS. 4 and 5).

In a twelfth aspect, alone or in combination with one or more of the first through eleventh aspects, the configuration indicates the polar code sequence, from the uniform polar code sequence and the nonuniform polar code sequence, for the communication based at least in part on a channel type associated with the communication (e.g., as described in connection with FIGS. 4 and 5).

In a thirteenth aspect, alone or in combination with one or more of the first through twelfth aspects, the channel type associated with the communication is a PUCCH, a PDCCH, or a PBCH (e.g., as described in connection with FIGS. 4 and 5).

In a fourteenth aspect, alone or in combination with one or more of the first through thirteenth aspects, the configuration indicates the polar code sequence, from the uniform polar code sequence and the nonuniform polar code sequence, for the communication based at least in part on a type of UCI associated with the communication (e.g., as described in connection with FIGS. 4 and 5).

In a fifteenth aspect, alone or in combination with one or more of the first through fourteenth aspects, the type of UCI associated with the communication is a HARQ message, a CSI message, or both (e.g., as described in connection with FIGS. 4 and 5).

In a sixteenth aspect, alone or in combination with one or more of the first through fifteenth aspects, the control signaling comprises RRC signaling or a MAC-CE.

Although FIG. 7 shows example blocks of process 700, in some aspects (e.g., as described in connection with FIGS. 4 and 5), process 700 may include additional blocks, fewer blocks, different blocks, or differently arranged blocks than those depicted in FIG. 7. Additionally, or alternatively, two or more of the blocks of process 700 may be performed in parallel.

FIG. 8 is a diagram of an example apparatus 800 for wireless communication, in accordance with the present disclosure. The apparatus 800 may be a wireless communication device (e.g., a UE 120, a network node 110, a wireless communication device 405, a wireless communication device 505), or a wireless communication device may include the apparatus 800. In some aspects, the apparatus 800 includes a reception component 802, a transmission component 804, and/or a communication manager 806, which may be in communication with one another (for example, via one or more buses and/or one or more other components). In some aspects, the communication manager 806 is the communication manager 150 or the communication manager 155 described in connection with FIG. 1. As shown, the apparatus 800 may communicate with another apparatus 808, such as a UE or a network node (such as a CU, a DU, an RU, or a base station), using the reception component 802 and the transmission component 804. The communication manager 806 may be included in, or implemented via, a processing system (for example, the processing system 140 or the processing system 145 described in connection with FIG. 1) of the wireless communication device.

In some aspects, the apparatus 800 may be configured to perform one or more operations described herein in connection with FIGS. 3-5. Additionally, or alternatively, the apparatus 800 may be configured to perform one or more processes described herein, such as process 600 of FIG. 6, process 700 of FIG. 7, or a combination thereof. In some aspects, the apparatus 800 and/or one or more components shown in FIG. 8 may include one or more components of the wireless communication device described in connection with FIG. 1. Additionally, or alternatively, one or more components shown in FIG. 8 may be implemented within one or more components described in connection with FIG. 1. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 802 may receive communications, such as reference signals, control information, data communications, or a combination thereof, from the apparatus 808. The reception component 802 may provide received communications to one or more other components of the apparatus 800. In some aspects, the reception component 802 may perform signal processing on the received communications, and may provide the processed signals to the one or more other components of the apparatus 800. In some aspects, the reception component 802 may include one or more components of the wireless communication device described above in connection with FIG. 1, such as a radio, one or more RF chains, one or more transceivers, or one or more modems, each of which may in turn be coupled with one or more antennas of the wireless communication device.

The transmission component 804 may transmit communications, such as reference signals, control information, data communications, or a combination thereof, to the apparatus 808. In some aspects, one or more other components of the apparatus 800 may generate communications and may provide the generated communications to the transmission component 804 for transmission to the apparatus 808. In some aspects, the transmission component 804 may perform signal processing on the generated communications, and may transmit the processed signals to the apparatus 808. In some aspects, the transmission component 804 may include one or more components of the wireless communication device described above in connection with FIG. 1, such as a radio, one or more RF chains, one or more transceivers, or one or more modems, each of which may in turn be coupled with one or more antennas of the wireless communication device described in connection with FIG. 1. In some aspects, the transmission component 804 may be co-located with the reception component 802.

The communication manager 806 may support operations of the reception component 802 and/or the transmission component 804. For example, the communication manager 806 may receive information associated with configuring reception of communications by the reception component 802 and/or transmission of communications by the transmission component 804. Additionally, or alternatively, the communication manager 806 may generate and/or provide control information to the reception component 802 and/or the transmission component 804 to control reception and/or transmission of communications.

The reception component 802 may receive control signaling indicating a configuration for a communication. Additionally, or alternatively, the transmission component 804 may transmit the control signaling indicating the configuration for the communication. The communication manager 806 may select one of a uniform polar code sequence or a nonuniform polar code sequence based at least in part on the configuration for the communication. The communication manager 806 may derive, based at least in part on a polar code sequence that is selected, a polar code for encoding a plurality of bits to generate a polar codeword for the communication. The communication manager 806 may encode the plurality of bits using the polar code to generate the polar codeword. The transmission component 804 may transmit the polar codeword within the communication.

The communication manager 806 may generate the nonuniform polar code sequence based at least in part on the uniform polar code sequence, wherein the encoding is based at least in part on the generating.

The communication manager 806 may store the nonuniform polar code sequence at the wireless communication device, wherein the selecting is based at least in part on the storing.

The reception component 802 may receive control signaling indicating a configuration for a communication. Additionally, or alternatively, the transmission component 804 may transmit the control signaling indicating the configuration for the communication. The reception component 802 may receive the communication based at least in part on the configuration, wherein the communication comprises a polar codeword. The communication manager 806 may select one of a uniform polar code sequence or a nonuniform polar code sequence based at least in part on the configuration for the communication. The communication manager 806 may derive, based at least in part on a polar code sequence that is selected, a polar code for decoding the polar codeword to obtain a plurality of bits. The communication manager 806 may decode the polar codeword using the polar code to obtain the plurality of bits.

The communication manager 806 may generate the nonuniform polar code sequence based at least in part on the uniform polar code sequence, wherein the decoding is based at least in part on the generating.

The communication manager 806 may store the nonuniform polar code sequence at the wireless communication device, wherein the selecting is based at least in part on the storing.

The number and arrangement of components shown in FIG. 8 are provided as an example. In practice, there may be additional components, fewer components, different components, or differently arranged components than those shown in FIG. 8. Furthermore, two or more components shown in FIG. 8 may be implemented within a single component, or a single component shown in FIG. 8 may be implemented as multiple, distributed components. Additionally, or alternatively, a set of (one or more) components shown in FIG. 8 may perform one or more functions described as being performed by another set of components shown in FIG. 8.

The following provides an overview of some Aspects of the present disclosure:
Aspect 1: A method for wireless communication at a wireless communication device, comprising: receiving control signaling indicating a configuration for a communication; selecting one of a uniform polar code sequence or a nonuniform polar code sequence based at least in part on the configuration for the communication; deriving, based at least in part on a polar code sequence that is selected, a polar code for encoding a plurality of bits to generate a polar codeword for the communication; encoding the plurality of bits using the polar code to generate the polar codeword; and transmitting the polar codeword within the communication.

Aspect 2: The method of Aspect 1, wherein the configuration indicates the polar code sequence, from the uniform polar code sequence and the nonuniform polar code sequence, for the encoding for the communication.

Aspect 3: The method of any of Aspects 1-2, further comprising: generating the nonuniform polar code sequence based at least in part on the uniform polar code sequence, wherein the encoding is based at least in part on the generating.

Aspect 4: The method of Aspect 3, wherein the generating comprises: applying, to a first plurality of channels associated with a first plurality of information bit locations of the uniform polar code sequence, a log-likelihood ratio bias to identify a first plurality of channel capacities; and identifying, based at least in part on the first plurality of channel capacities, a second plurality of information bit locations associated with the nonuniform polar code sequence.

Aspect 5: The method of Aspect 3, further comprising: storing the nonuniform polar code sequence at the wireless communication device, wherein the selecting is based at least in part on the storing.

Aspect 6: The method of any of Aspects 1-5, wherein the uniform polar code sequence and the nonuniform polar code sequence are predefined.

Aspect 7: The method of any of Aspects 1-6, wherein: the uniform polar code sequence is associated with polar encoding uniformly distributed bits; and the nonuniform polar code sequence is associated with polar encoding nonuniformly distributed bits.

Aspect 8: The method of any of Aspects 1-7, wherein: the uniform polar code sequence comprises a first subset of bit locations in the uniform polar code sequence that comprises a first half of the bit locations in the uniform polar code sequence that have larger indices than a second half of the bit locations in the uniform polar code sequence; the nonuniform polar code sequence comprises a second subset of bit locations in the nonuniform polar code sequence that comprises a first half of the bit locations in the nonuniform polar code sequence that have larger indices than a second half of the bit locations in the nonuniform polar code sequence; and a first quantity of information bit locations in the first subset of bit locations in the uniform polar code sequence is less than a second quantity of information bit locations in the second subset of bit locations in the nonuniform polar code sequence.

Aspect 9: The method of any of Aspects 1-8, wherein a first size of the uniform polar code sequence is different from a second size of the nonuniform polar code sequence.

Aspect 10: The method of Aspect 9, wherein the first size is greater than the second size.

Aspect 11: The method of any of Aspects 1-10, wherein the configuration indicates the polar code sequence, from the uniform polar code sequence and the nonuniform polar code sequence, for the communication based at least in part on a downlink control information format of the communication, a search space associated with the communication, or a control resource set associated with the communication.

Aspect 12: The method of any of Aspects 1-11, wherein the configuration indicates the polar code sequence, from the uniform polar code sequence and the nonuniform polar code sequence, for the communication based at least in part on PUCCH format associated with the communication, a PUCCH resource associated with the communication, or a PUCCH resource set associated with the communication.

Aspect 13: The method of any of Aspects 1-12, wherein the configuration indicates the polar code sequence, from the uniform polar code sequence and the nonuniform polar code sequence, for the communication based at least in part on a channel type associated with the communication.

Aspect 14: The method of Aspect 13, wherein the channel type associated with the communication is a PUCCH, a PDCCH, or a PBCH.

Aspect 15: The method of any of Aspects 1-14, wherein the configuration indicates the polar code sequence, from the uniform polar code sequence and the nonuniform polar code sequence, for the communication based at least in part on a type of UCI associated with the communication.

Aspect 16: The method of Aspect 15, wherein the type of UCI associated with the communication is a HARQ message, a CSI message, or both.

Aspect 17: The method of any of Aspects 1-16, wherein the control signaling comprises RRC signaling or a MAC-CE.

Aspect 18: A method for wireless communication at a wireless communication device, comprising: receiving control signaling indicating a configuration for a communication; receiving the communication based at least in part on the configuration, wherein the communication comprises a polar codeword; selecting one of a uniform polar code sequence or a nonuniform polar code sequence based at least in part on the configuration for the communication; deriving, based at least in part on a polar code sequence that is selected, a polar code for decoding the polar codeword to obtain a plurality of bits; and decoding the polar codeword using the polar code to obtain the plurality of bits.

Aspect 19: The method of Aspect 18, wherein the configuration indicates the polar code sequence, from the uniform polar code sequence and the nonuniform polar code sequence, for the decoding for the communication.

Aspect 20: The method of any of Aspects 18-19, further comprising: generating the nonuniform polar code sequence based at least in part on the uniform polar code sequence, wherein the decoding is based at least in part on the generating.

Aspect 21: The method of Aspect 20, wherein the generating comprises: applying, to a first plurality of channels associated with a first plurality of information bit locations of the uniform polar code sequence, a log-likelihood ratio bias to identify a first plurality of channel capacities; and identifying, based at least in part on the first plurality of channel capacities, a second plurality of information bit locations associated with the nonuniform polar code sequence.

Aspect 22: The method of Aspect 20, further comprising: storing the nonuniform polar code sequence at the wireless communication device, wherein the selecting is based at least in part on the storing.

Aspect 23: The method of any of Aspects 18-22, wherein the uniform polar code sequence and the nonuniform polar code sequence are predefined.

Aspect 24: The method of any of Aspects 18-23, wherein: the uniform polar code sequence is associated with polar decoding uniformly distributed bits; and the nonuniform polar code sequence is associated with polar decoding nonuniformly distributed bits.

Aspect 25: The method of any of Aspects 18-24, wherein: the uniform polar code sequence comprises a first subset of bit locations in the uniform polar code sequence that comprises a first half of the bit locations in the uniform polar code sequence that have larger indices than a second half of the bit locations in the uniform polar code sequence; the nonuniform polar code sequence comprises a second subset of bit locations in the nonuniform polar code sequence that comprises a first half of the bit locations in the nonuniform polar code sequence that have larger indices than a second half of the bit locations in the nonuniform polar code sequence; and a first quantity of information bit locations in the first subset of bit locations in the uniform polar code sequence is less than a second quantity of information bit locations in the second subset of bit locations in the nonuniform polar code sequence.

Aspect 26: The method of any of Aspects 18-25, wherein a first size of the uniform polar code sequence is different from a second size of the nonuniform polar code sequence.

Aspect 27: The method of Aspect 26, wherein the first size is greater than the second size.

Aspect 28: The method of any of Aspects 18-27, wherein the configuration indicates the polar code sequence, from the uniform polar code sequence and the nonuniform polar code sequence, for the communication based at least in part on a downlink control information format of the communication, a search space associated with the communication, or a control resource set associated with the communication.

Aspect 29: The method of any of Aspects 18-28, wherein the configuration indicates the polar code sequence, from the uniform polar code sequence and the nonuniform polar code sequence, for the communication based at least in part on PUCCH format associated with the communication, a PUCCH resource associated with the communication, or a PUCCH resource set associated with the communication.

Aspect 30: The method of any of Aspects 18-29, wherein the configuration indicates the polar code sequence, from the uniform polar code sequence and the nonuniform polar code sequence, for the communication based at least in part on a channel type associated with the communication.

Aspect 31: The method of Aspect 30, wherein the channel type associated with the communication is a PUCCH, a PDCCH, or a PBCH.

Aspect 32: The method of any of Aspects 18-31, wherein the configuration indicates the polar code sequence, from the uniform polar code sequence and the nonuniform polar code sequence, for the communication based at least in part on a type of UCI associated with the communication.

Aspect 33: The method of Aspect 32, wherein the type of UCI associated with the communication is a HARQ message, a CSI message, or both.

Aspect 34: The method of any of Aspects 18-33, wherein the control signaling comprises RRC signaling or a MAC-CE.

Aspect 35: An apparatus for wireless communication at a device, the apparatus comprising one or more processors; one or more memories coupled with the one or more processors; and instructions stored in the one or more memories and executable by the one or more processors to cause the apparatus to perform the method of one or more of Aspects 1-34.

Aspect 36: An apparatus for wireless communication at a device, the apparatus comprising one or more memories and one or more processors coupled to the one or more memories, the one or more processors configured to cause the device to perform the method of one or more of Aspects 1-34.

Aspect 37: An apparatus for wireless communication, the apparatus comprising at least one means for performing the method of one or more of Aspects 1-34.

Aspect 38: A non-transitory computer-readable medium storing code for wireless communication, the code comprising instructions executable by one or more processors to perform the method of one or more of Aspects 1-34.

Aspect 39: A non-transitory computer-readable medium storing a set of instructions for wireless communication, the set of instructions comprising one or more instructions that, when executed by one or more processors of a device, cause the device to perform the method of one or more of Aspects 1-34.

Aspect 40: A device for wireless communication, the device comprising a processing system that includes one or more processors and one or more memories coupled with the one or more processors, the processing system configured to cause the device to perform the method of one or more of Aspects 1-34.

Aspect 41: An apparatus for wireless communication at a device, the apparatus comprising one or more memories and one or more processors coupled to the one or more memories, the one or more processors individually or collectively configured to cause the device to perform the method of one or more of Aspects 1-34.

The foregoing disclosure provides illustration and description but is not intended to be exhaustive or to limit the aspects to the precise forms disclosed. Modifications and variations may be made in light of the above disclosure or may be acquired from practice of the aspects. No element, act, or instruction described herein should be construed as critical or essential unless explicitly described as such.

It will be apparent that systems or methods described herein may be implemented in different forms of hardware or a combination of hardware and software. The actual specialized control hardware or software used to implement these systems or methods is not limiting of the aspects. Thus, the operation and behavior of the systems or methods are described herein without reference to specific software code, because those skilled in the art will understand that software and hardware can be designed to implement the systems or methods based, at least in part, on the description herein. A component being configured to perform a function means that the component has a capability to perform the function, and does not require the function to be actually performed by the component, unless noted otherwise.

As used herein, the articles “a” and “an” are intended to refer to one or more items and may be used interchangeably with “one or more” or “at least one.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or “a single one” or similar language is used. Also, as used herein, the terms “has,” “have,” “having,” “comprise,” “comprising,” “include” and “including,” and derivatives thereof or similar terms are intended to be open-ended terms that do not limit an element that they modify (for example, an element “having” A may also have B). Also, as used herein, the term “or” is intended to be inclusive when used in a series and may be used interchangeably with “and/or,” unless explicitly stated otherwise (for example, if used in combination with “either” or “only one of”). As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (for example, a+a, a+a+a, a+a+b, a+a+c, a+b+b, a+c+c, b+b, b+b+b, b+b+c, c+c, and c+c+c, or any other ordering of a, b, and c).

As used herein, the term “determine” or “determining” encompasses a wide variety of actions and, therefore, “determining” can include calculating, computing, processing, deriving, estimating, investigating, looking up (such as via looking up in a table, a database, or another data structure), searching, inferring, ascertaining, and/or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing, and/or other such similar actions.

As used herein, the phrase “based on” is intended to mean “based at least in part on” or “based on or otherwise in association with” unless explicitly stated otherwise. As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

Even though particular combinations of features are recited in the claims or disclosed in the specification, these combinations are not intended to limit the scope of all aspects described herein. Many of these features may be combined in ways not specifically recited in the claims or disclosed in the specification. The disclosure of various aspects includes each dependent claim in combination with every other claim in the claim set.

What is claimed is:

1. An apparatus for wireless communication at a wireless communication device, comprising:
one or more memories; and
one or more processors, coupled to the one or more memories, configured to cause the wireless communication device to:
receive control signaling indicating a configuration for a communication;
select one of a uniform polar code sequence or a nonuniform polar code sequence based at least in part on the configuration for the communication;
derive, based at least in part on a polar code sequence that is selected, a polar code for encoding a plurality of bits to generate a polar codeword for the communication;
encode the plurality of bits using the polar code to generate the polar codeword; and
transmit the polar codeword within the communication.

2. The apparatus of claim 1, wherein the configuration indicates the polar code sequence, from the uniform polar code sequence and the nonuniform polar code sequence, for the encoding for the communication.

3. The apparatus of claim 1, wherein the one or more processors are further configured to cause the wireless communication device to:
generate the nonuniform polar code sequence based at least in part on the uniform polar code sequence, wherein the encoding is based at least in part on the generating.

4. The apparatus of claim 3, wherein to generate the nonuniform polar code sequence, the one or more processors are further configured to cause the wireless communication device to:
apply, to a first plurality of channels associated with a first plurality of information bit locations of the uniform polar code sequence, a log-likelihood ratio bias to identify a first plurality of channel capacities; and
identify, based at least in part on the first plurality of channel capacities, a second plurality of information bit locations associated with the nonuniform polar code sequence.

5. The apparatus of claim 3, wherein the one or more processors are further configured to cause the wireless communication device to:
store the nonuniform polar code sequence at the wireless communication device, wherein the selecting is based at least in part on the storing.

6. The apparatus of claim 1, wherein the uniform polar code sequence and the nonuniform polar code sequence are predefined.

7. The apparatus of claim 1, wherein:
the uniform polar code sequence is associated with polar encoding uniformly distributed bits; and
the nonuniform polar code sequence is associated with polar encoding nonuniformly distributed bits.

8. The apparatus of claim 1, wherein:
the uniform polar code sequence comprises a first subset of bit locations in the uniform polar code sequence that comprises a first half of the bit locations in the uniform polar code sequence that have larger indices than a second half of the bit locations in the uniform polar code sequence;
the nonuniform polar code sequence comprises a second subset of bit locations in the nonuniform polar code sequence that comprises a first half of the bit locations in the nonuniform polar code sequence that have larger indices than a second half of the bit locations in the nonuniform polar code sequence; and
a first quantity of information bit locations in the first subset of bit locations in the uniform polar code sequence is less than a second quantity of information bit locations in the second subset of bit locations in the nonuniform polar code sequence.

9. The apparatus of claim 1, wherein a first size of the uniform polar code sequence is different from a second size of the nonuniform polar code sequence.

10. The apparatus of claim 9, wherein the first size is greater than the second size.

11. The apparatus of claim 1, wherein the configuration indicates the polar code sequence, from the uniform polar code sequence and the nonuniform polar code sequence, for the communication based at least in part on a downlink control information format of the communication, a search space associated with the communication, or a control resource set associated with the communication.

12. The apparatus of claim 1, wherein the configuration indicates the polar code sequence, from the uniform polar code sequence and the nonuniform polar code sequence, for the communication based at least in part on physical uplink control channel (PUCCH) format associated with the communication, a PUCCH resource associated with the communication, or a PUCCH resource set associated with the communication.

13. The apparatus of claim 1, wherein the configuration indicates the polar code sequence, from the uniform polar code sequence and the nonuniform polar code sequence, for the communication based at least in part on a channel type associated with the communication.

14. The apparatus of claim 13, wherein the channel type associated with the communication is a physical uplink control channel (PUCCH), a physical downlink control channel (PDCCH), or a physical broadcast channel (PBCH).

15. The apparatus of claim 1, wherein the configuration indicates the polar code sequence, from the uniform polar code sequence and the nonuniform polar code sequence, for the communication based at least in part on a type of uplink control information associated with the communication.

16. The apparatus of claim 15, wherein the type of uplink control information associated with the communication is a hybrid automatic repeat request (HARQ) message, a channel state information message, or both.

17. The apparatus of claim 1, wherein the control signaling comprises radio resource control signaling or a medium access control control element.

18. An apparatus for wireless communication at a wireless communication device, comprising:
one or more memories; and
one or more processors, coupled to the one or more memories, configured to cause the wireless communication device to:
receive control signaling indicating a configuration for a communication;
receive the communication based at least in part on the configuration, wherein the communication comprises a polar codeword;
select one of a uniform polar code sequence or a nonuniform polar code sequence based at least in part on the configuration for the communication;
derive, based at least in part on a polar code sequence that is selected, a polar code for decoding the polar codeword to obtain a plurality of bits; and
decode the polar codeword using the polar code to obtain the plurality of bits.

19. The apparatus of claim 18, wherein the configuration indicates the polar code sequence, from the uniform polar code sequence and the nonuniform polar code sequence, for the decoding for the communication.

20. The apparatus of claim 18, wherein the one or more processors are further configured to cause the wireless communication device to:
generate the nonuniform polar code sequence based at least in part on the uniform polar code sequence, wherein the decoding is based at least in part on the generating.

21. The apparatus of claim 20, wherein to generate the nonuniform polar code sequence, the one or more processors are further configured to cause the wireless communication device to:
apply, to a first plurality of channels associated with a first plurality of information bit locations of the uniform polar code sequence, a log-likelihood ratio bias to identify a first plurality of channel capacities; and
identify, based at least in part on the first plurality of channel capacities, a second plurality of information bit locations associated with the nonuniform polar code sequence.

22. The apparatus of claim 20, wherein the one or more processors are further configured to cause the wireless communication device to:
store the nonuniform polar code sequence at the wireless communication device, wherein the selecting is based at least in part on the storing.

23. The apparatus of claim 18, wherein the uniform polar code sequence and the nonuniform polar code sequence are predefined.

24. The apparatus of claim 18, wherein:
the uniform polar code sequence comprises a first subset of bit locations in the uniform polar code sequence that comprises a first half of the bit locations in the uniform polar code sequence that have larger indices than a second half of the bit locations in the uniform polar code sequence;
the nonuniform polar code sequence comprises a second subset of bit locations in the nonuniform polar code sequence that comprises a first half of the bit locations in the nonuniform polar code sequence that have larger indices than a second half of the bit locations in the nonuniform polar code sequence; and
a first quantity of information bit locations in the first subset of bit locations in the uniform polar code sequence is less than a second quantity of information bit locations in the second subset of bit locations in the nonuniform polar code sequence.

25. The apparatus of claim 18, wherein a first size of the uniform polar code sequence is different from a second size of the nonuniform polar code sequence.

26. The apparatus of claim 18, wherein the configuration indicates the polar code sequence, from the uniform polar code sequence and the nonuniform polar code sequence, for the communication based at least in part on a downlink control information format of the communication, a search space associated with the communication, or a control resource set associated with the communication.

27. The apparatus of claim 18, wherein the configuration indicates the polar code sequence, from the uniform polar code sequence and the nonuniform polar code sequence, for the communication based at least in part on physical uplink control channel (PUCCH) format associated with the communication, a PUCCH resource associated with the communication, or a PUCCH resource set associated with the communication.

28. The apparatus of claim 18, wherein the configuration indicates the polar code sequence, from the uniform polar code sequence and the nonuniform polar code sequence, for the communication based at least in part on a channel type associated with the communication.

29. A method for wireless communication at a wireless communication device, comprising:
receiving control signaling indicating a configuration for a communication;
selecting one of a uniform polar code sequence or a nonuniform polar code sequence based at least in part on the configuration for the communication;
deriving, based at least in part on a polar code sequence that is selected, a polar code for encoding a plurality of bits to generate a polar codeword for the communication;
encoding the plurality of bits using the polar code to generate the polar codeword; and
transmitting the polar codeword within the communication.

30. A method for wireless communication at a wireless communication device, comprising:
receiving control signaling indicating a configuration for a communication;
receiving the communication based at least in part on the configuration, wherein the communication comprises a polar codeword;
selecting one of a uniform polar code sequence or a nonuniform polar code sequence based at least in part on the configuration for the communication;
deriving, based at least in part on a polar code sequence that is selected, a polar code for decoding the polar codeword to obtain a plurality of bits; and
decoding the polar codeword using the polar code to obtain the plurality of bits.
